(19) United States
(12) Patent Application Publication
(10) Pub. No.: US 2014/0235068 A1
(43) Pub. Date: Aug. 21, 2014

(54) METHOD OF MANUFACTURING SEMICONDUCTOR DEVICE, APPARATUS FOR MANUFACTURING SEMICONDUCTOR DEVICE, AND NON-TRANSITORY COMPUTER-READABLE RECORDING MEDIUM

(71) Applicant: Hitachi Kokusai Electric Inc., Tokyo (JP)

(72) Inventors: Hiroshi ASHIHARA, Toyama-shi (JP); Tomihiro AMANO, Toyama-shi (JP); Shin HIYAMA, Toyama-shi (JP); Harunobu SAKUMA, Toyama-shi (JP); Yuichi WADA, Toyama-shi (JP); Hideto TATENO, Toyama-shi (JP)

(73) Assignee: Hitachi Kokusai Electric Inc., Tokyo (JP)

(21) Appl. No.: 14/266,208

(22) Filed: Apr. 30, 2014

Related U.S. Application Data
(63) Continuation of application No. PCT/JP2012/078284, filed on Jan. 11, 2012.

(30) Foreign Application Priority Data
Nov. 1, 2011 (JP) 2011-240144
Mar. 28, 2012 (JP) 2012-073753

(51) Int. Cl. H01L 21/02; H01L 21/67

(52) U.S. Cl. CPC H01L 21/02236; H01L 21/02164; H01L 21/02255; H01L 21/67017
USPC 438/771; 118/50; 118/58

(57) ABSTRACT

Provided is a method of manufacturing a semiconductor device. The method includes (a) loading a substrate having a silicon-containing film formed thereon into a process chamber; (b) supplying a gas into the process chamber from a gas supply unit until an inner pressure of the process chamber is equal to or greater than atmospheric pressure; and (c) supplying a process liquid from a process liquid supply unit to the substrate to oxidize the silicon-containing film.

### CROSS-REFERENCE TO RELATED PATENT APPLICATION

This application is a continuation of International Application No. PCT/JP2012/078284 filed on Nov. 1, 2012, which claims priority under 35 U.S.C. §119 to Japanese Patent Application Nos. 2011-240144 and 2012-073753 filed on Nov. 1, 2011 and Mar. 28, 2012, respectively, in the Japanese Patent Office, the entire contents of which are hereby incorporated by reference.

### BACKGROUND OF THE INVENTION

1. Field of the Invention

The present invention relates to a method of manufacturing a semiconductor device, an apparatus for manufacturing the semiconductor device, and a non-transitory computer-readable recording medium.

2. Description of the Related Art

Technical difficulties in processing techniques of controlling leakage current interference between transistor elements in accordance with miniaturization of a semiconductor device such as a large scale integrated circuit (hereinafter referred to as “LSI”) or the like have gradually been increasing. In general, separation of elements of an LSI is performed through a method of forming a gap such as a groove, a hole, or the like between elements of a substrate, such as a silicon substrate made of silicon (Si), which are desired to be separated and depositing an insulating material in the gap. As the insulating material, an oxide film may be mainly used. As the oxide film, for example, a silicon oxide film may be used. The silicon oxide film is formed on the substrate by natural oxidation or a chemical vapor deposition (CVD) method. In Japanese Unexamined Patent Application Publication No. 2010-87475, an example of a method of forming an insulating film by the CVD method is disclosed.

Due to the miniaturization of semiconductor devices in recent years, the gap in a minute structure which is vertically deep or laterally narrow is formed on the substrate. By burying the gap having the minute structure using the CVD method, an oxide film may be formed. However, depositing the gap with the minute structure using the CVD method has reached its technical limit.

Therefore, a burying method using an oxide having fluidity, that is, a spin on dielectric (SOD) method (insulating material coating method) has attracted attention. In the SOD method, a coating insulating material containing an inorganic or organic component which is called spin on glass (SOG) is used. The burying method using the coating insulating material was employed in the manufacturing process of LSIs before the advent of oxide films on substrates using the above-described CVD method.

In recent years, in semiconductor devices represented by an LSI, a dynamic random access memory (DRAM), a flash memory, and the like, the minimum processing dimension has become less than 50 nm in width. However, in the SOD method, the processing dimension is about 0.35 μm to 1 μm, which is not minute. Thus, there are difficulties in forming an oxide film on a substrate having a minute structure while maintaining the quality as an insulating film.

Therefore, in recent years, in the SOD method, use of a silicon material such as polysilazane or the like as a substitute material for SOG has been studied. However, it is known that the silicon material such as polysilazane or the like contains nitrogen resulting from ammonia as an impurity. As a result, there may be cases in which nitrogen is contained even in an insulating film formed using the silicon material such as polysilazane or the like. In addition, the molecular structure of polysilazane is disclosed in Japanese Unexamined Patent Application Publication No. 2010-111842.

### SUMMARY OF THE INVENTION

Therefore, in order to remove impurities such as nitrogen contained in the insulating film formed using the silicon material such as polysilazane or the like and improve the film quality of the insulating film, it is necessary to perform a heat treatment of heating the substrate to approximately 1,000° C.

However, reduction of a heat load of a transistor is being demanded. The heat load should be reduced in order to prevent excessive diffusion of impurities such as boron, arsenic, phosphorus, or the like which are injected for operation of the transistor, to prevent cohesion of a metal silicide for an electrode, to prevent performance variation of work function metal materials for a gate, to write to a memory device, to ensure a read repetition life time, and the like. Thus, it is difficult to maintain insulation film qualities of the insulating film formed using the silicon material such as polysilazane or the like.

It is an object of the present invention to provide a method of manufacturing a semiconductor device which can improve the film quality of an oxide film formed on a substrate, an apparatus for manufacturing a semiconductor device, and a non-transitory computer-readable recording medium.

According to one aspect of the present invention, there is provided a method of manufacturing a semiconductor device, including: (a) loading a substrate having a silicon-containing film formed thereon into a process chamber; (b) supplying a gas into the process chamber from a gas supply unit until an inner pressure of the process chamber is equal to or greater than atmospheric pressure; and (c) supplying a process liquid from a process liquid supply unit to the substrate to oxidize the silicon-containing film.

According to another aspect of the present invention, there is provided an apparatus for manufacturing a semiconductor device, including: a process chamber configured to accommodate a substrate having a silicon-containing film formed thereon; a gas supply unit configured to supply a gas into the process chamber; a process liquid supply unit configured to supply a process liquid to the substrate; and a control unit configured to control the gas supply unit and the process liquid supply unit to supply the gas into the process chamber until an inner pressure of the process chamber is equal to or greater than atmospheric pressure while simultaneously supplying the process liquid to the substrate.

According to still another aspect of the present invention, there is provided a non-transitory computer-readable recording medium storing a program executable by a computer, the program including: (a) supplying a gas into a process chamber from a gas supply unit until an inner pressure of the process chamber is equal to or greater than atmospheric pressure; and (b) supplying a process liquid from a process liquid supply unit to a substrate accommodated in the process chamber and having a silicon-containing film formed thereon.

### BRIEF DESCRIPTION OF THE DRAWINGS

FIG. 1 is a schematic horizontal cross-sectional diagram of a substrate processing apparatus according to an embodiment of the present invention.

FIG. 2 is a schematic vertical cross-sectional diagram of a process chamber according to an embodiment of the present invention.

FIG. 3 is a schematic configuration diagram of a controller of a substrate processing apparatus which is desirably used according to an embodiment of the present invention.

FIG. 4 is a flowchart showing a substrate processing process according to an embodiment of the present invention.

FIG. 5 is a flowchart showing a substrate processing process according to another embodiment of the present invention.

FIG. 6 is a flowchart showing a substrate processing process according to another embodiment of the present invention.

FIG. 7 is a flowchart showing a substrate processing process according to another embodiment of the present invention.

FIG. 8 is a flowchart showing a substrate processing process according to another embodiment of the present invention.

FIG. 9 is a flowchart showing a substrate processing process according to another embodiment of the present invention.

FIG. 10 is a flowchart showing a substrate processing process according to another embodiment of the present invention.

FIG. 11 is a flowchart showing a substrate processing process according to another embodiment of the present invention.

FIG. 12 is a table showing an example of a process performed in each process chamber included in a substrate processing apparatus according to an embodiment of the present invention.

FIG. 13 is a schematic horizontal cross-sectional diagram of a substrate processing apparatus according to another embodiment of the present invention.

FIG. 14 is a graph of FT-IR spectral data of a silicon-containing film included in a substrate according to an embodiment of the present invention.

FIG. 15 is a graph of FT-IR spectral data of a silicon-containing film included in a substrate according to another embodiment of the present invention.

FIG. 16 is a graph of FT-IR spectral data of a silicon-containing film included in a substrate according to still another embodiment of the present invention.

### DETAILED DESCRIPTION OF THE PREFERRED EMBODIMENTS

### Embodiment

Hereinafter, an embodiment of the present invention will be described with reference to the accompanying drawings.

(1) Configuration of Substrate Processing Apparatus

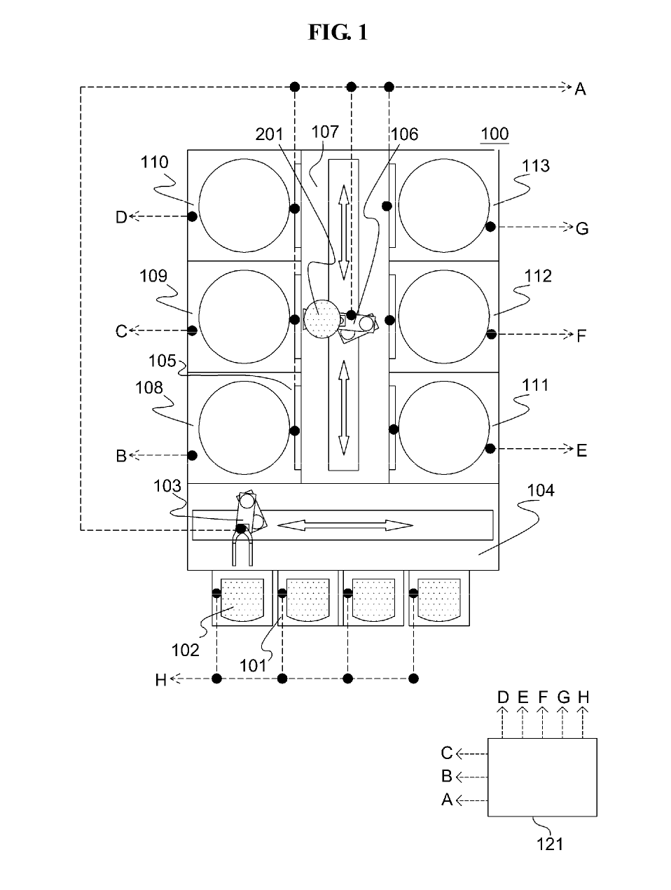

First, a configuration of the substrate processing apparatus according to an embodiment of the present invention will be described mainly with reference to FIG. 1. FIG. 1 is a schematic horizontal cross-sectional diagram of a substrate processing apparatus according to an embodiment of the present invention. In addition, in the following description, the front, back, left, and right are based on FIG. 1. That is, with respect to the page on which FIG. 1 is shown, the front is the top of the page, the back is the bottom of the page, and the left and right are the left and right of the page.

As shown in FIG. 1, the substrate processing apparatus 100 includes a transport chamber 107. In the transport chamber 107, a plurality of process chambers [six process chambers 108 to 113 in the present embodiment] are provided to communicate with the transport chamber 107 through gate valves 105, respectively. Each of the process chambers 108 to 113 is constituted to execute various kinds of substrate processing such as forming a silicon-containing film on a wafer 201 as a substrate, oxidizing the silicon-containing film formed on the wafer 201, drying the wafer 201, heating the wafer 201, and the like as will described later.

In addition, in the present embodiment, the six process chambers 108 to 113 are provided, but the present invention is not limited thereto. The process chambers may be changed to an arbitrary number of process chambers according to limitations of an installation space of the substrate processing apparatus 100, and the like. That is, the number of process chambers provided in the substrate processing apparatus 100 may be five or less or seven or more. In addition, disposition positions of the process chambers 108 to 113 may be appropriately changed according to limitations of the installation space of the substrate processing apparatus 100, and the like.

A load/unload arm 106 is provided as a first transport mechanism (transport robot) in the transport chamber 107. The load/unload arm 106 is constituted to transport the wafer 201 between the transport chamber 107 and each of the process chambers 108 to 113. The load/unload arm 106 is constituted to be elevated by an elevator provided in the transport chamber 107 and to reciprocate in the front and rear direction (the front and rear direction in FIG. 1) by, for example, a linear actuator.

An atmosphere transport chamber 104 which is used under approximately atmospheric pressure is provided at an atmosphere side of the substrate processing apparatus 100, that is, the front side of the transport chamber 107. The atmosphere transport chamber 104 is provided to communicate with the transport chamber 107 through the gate valve or the like. That is, the atmosphere transport chamber 104 is constituted to function as a delivery area of the wafer 201.

In the atmosphere transport chamber 104, a transport arm 103 is provided as a second transport mechanism (transport robot) that transports the wafer 201. The transport arm 103 is constituted to be elevated by an elevator provided in the atmosphere transport chamber 104 and to reciprocate left and right by, for example, a linear actuator.

A substrate transport port that transports the wafer 201 in and out of the atmosphere transport chamber 104 is provided at the front side of the atmosphere transport chamber 104. A wafer loader 101 (I/O stage) is provided outside the atmosphere transport chamber 104 through the substrate transport port. A cassette 102 that accommodates a plurality of wafers 201 is placed on the wafer loader 101. The cassette 102 is constituted to be loaded (fed) and unloaded (discharged) into/from the wafer loader 101 by, for example, a transport device (rail guided vehicle: RGV). In addition, in the present embodiment, four wafer loaders 101 are provided, but the number of wafer loaders 101 is not limited thereto, and may be appropriately changed to an arbitrary number.

A controller 121 which will be described later is electrically connected to each component of the substrate processing apparatus 100. That is, the controller 121 is constituted to control operations of the transport arm 103 and the gate valve 105 through a signal line A, operations of the process chamber 108 through a signal line B, operations of the process chamber 109 through a signal line C, operations of the process chamber 110 through a signal line D, operations of the process chamber 111 through a signal line E, operations of the process chamber 112 through a signal line F, operations of the process chamber 113 through a signal line G, and operations of the cassette 102 through a signal line H.

(2) Operation of Substrate Processing Apparatus

Next, operations of the substrate processing apparatus 100 according to an embodiment of the present invention will be described.

First, for example, the cassette 102 in which 25 unprocessed wafers 201 are accommodated is loaded into the substrate processing apparatus 100 by the transport device. The loaded cassette 102 is placed on the wafer loader 101. In addition, the transport arm 103 provided in the atmosphere transport chamber 104 picks up the wafers 201 to load the wafers 201 into the transport chamber 104. Next, the atmosphere transport chamber 104 communicates with the transport chamber 107. Subsequently, the transport arm 103 loads the wafers 201 into the transport chamber 107, and delivers the wafers 201 to the load/unload arm 106 provided in the transport chamber 107. Next, the transport arm 103 repeatedly performs the above-described operations.

When delivery of the wafers 201 by the transport arm 103 is completed, the gate valve between the atmosphere transport chamber 104 and the transport chamber 107 is closed. In addition, an exhaust device provided in the transport chamber 107 may be adjusted so that the inside of the transport chamber 107 has a predetermined pressure.

When the gate valve between the atmosphere transport chamber 104 and the transport chamber 107 is closed, the gate valve 105 is opened so that the transport chamber 104 and the process chamber 108 communicate with each other. Next, the load/unload arm 106 loads the wafers 201 into the process chamber 108. When loading of the wafers 201 into the process chamber 108 is completed, the gate valve 105 is closed. In addition, a predetermined processing is performed on the wafers 201 in the process chamber 108.

When the predetermined processing in the process chamber 108 is completed, the gate valve 105 is opened and the wafers 201 are unloaded from the process chamber 108 and loaded into the transport chamber 107 108 by the load/unload arm 106. After the wafers 201 are unloaded, the gate valve 105 is closed.

Subsequently, the transport chamber 107 and the atmosphere transport chamber 107 communicate with each other. Next, the wafers 201 which have been unloaded from the process chamber 108 are picked up by the transport arm 103 to be loaded into the atmosphere transport chamber 104. Next, the processed wafers 201 are accommodated in the cassette 102 by the transport arm 103 through the substrate transport port of the atmosphere transport chamber 104.

Here, the cassette 102 may be kept opened until the maximum of 25 wafers 201 are accommodated again in the cassette 102, or the cassette 102 which has unloaded the wafers 201 may accommodate the wafers 201 again without accommodating the wafers 201 in the empty cassette 102.

When the predetermined processing is performed on all of the wafers 201 accommodated in the cassette 102 and all 25 of the wafers 201 having been processed are accommodated in the predetermined cassette 102, the cassette 102 is closed. Next, the cassette 102 is transported to the following process from the wafer loader 102 by the transport device. The above-described operations are repeatedly performed, and therefore each of the 25 wafers 201 may be sequentially processed.

In the present embodiment, an example of using the process chamber 108 has been described, but the present invention is not limited thereto. The same processing is performed when the process chambers 109 to 112 are used. In addition, the same processing may be performed in each of the process chambers 108 to 113, or a different processing may be performed in each of the process chambers 108 to 113. In addition, when a different processing is performed in each of the process chambers 108 and 109, a predetermined processing is performed on the wafer 201 in the process chamber 108 and then a different processing may be continuously performed in the process chamber 109.

(3) Configuration of Process Chamber

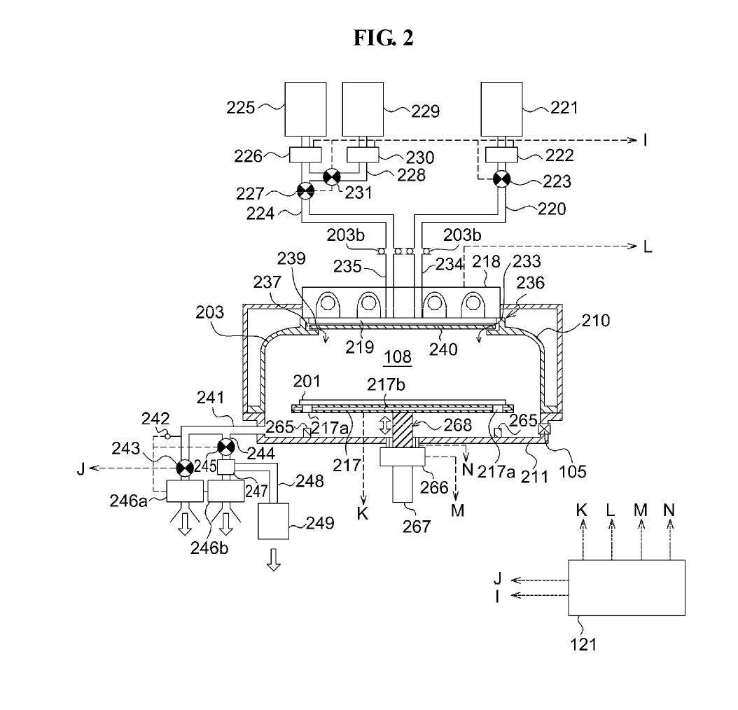

Next, the configuration of the process chamber 108 will be described mainly with reference to FIG. 2. FIG. 2 is a schematic vertical cross-sectional diagram of the process chamber 108 according to an embodiment of the present invention. Also, the process chambers 109 to 113 may be constituted in the same manner as in the process chamber 108, and thus detailed description thereof will be omitted.

A reaction vessel 203 constituting the process chamber 108 includes an upper vessel 210 which is a dome-shaped first vessel and a lower vessel 211 which is a bowl-shaped second vessel. In addition, the process chamber 108 is formed in such a manner that the upper vessel 210 is covered on the lower vessel 211. The upper vessel 210 is made of a nonmetallic material such as aluminum oxide (Al₂O₃), quartz (SiO₂), or the like, and the lower vessel 211 is made of nonmetallic materials such as aluminum oxide (Al₂O₃), quartz (SiO₂), silicon carbide (SiC), or the like. In addition, the upper vessel 210 and the lower vessel 211 may be made of a metal material such as aluminum (Al), steel use stainless (SUS), or the like. When the upper vessel 210 and the lower vessel 211 are made of a metal material, a surface of the metal material is preferably coated with a non-metallic material such as Al₂O₃, SiO₂, SiC, or the like in order to prevent reaction of the metal and a process liquid which will be described later.

The gate valve 105 is provided on a side wall of the lower vessel 211. As described above, the process chamber 108 is provided to communicate with the transport chamber 107 (see FIG. 1) through the gate valve 105. That is, a wafer 201 is provided to be transported between the process chamber 108 and the transport chamber 107. When the gate valve 105 is opened, the wafer 201 is loaded into the process chamber 108 using the load/unload arm 106 (see FIG. 1) as a transport robot, or unloaded from the process chamber 108. In addition, the inside of the process chamber 108 is sealed by closing the gate valve 105.

At the center of a bottom side in the process chamber 108, a susceptor 217 that supports the wafer 201 is disposed. The susceptor 217 is made of a nonmetallic material such as aluminum nitride (AlN), a ceramic, quartz (SiO₂), silicon carbide (SiC), or the like to reduce metal contamination of the wafer.

In the susceptor 217, an elevating mechanism 268 that elevates the susceptor 217 is provided. In addition, a plurality of through holes 217a are provided in the susceptor 217. A plurality of wafer elevating pins 265 which support a rear surface of the wafer 201 by elevating the wafer 201 are provided in positions corresponding to the through holes 217a of the bottom surface of the lower vessel 211. When the wafer elevating pins 265 are raised or when the susceptor 217 is lowered by the elevating mechanism 268, the wafer elevating pins 265 and the through holes 217a are disposed so that the wafer elevating pins 265 pass through the through-holes 217a without coming in contact with the susceptor 217.

A rotation mechanism 267 that rotates the susceptor 217 is provided in the elevating mechanism 268. A rotation shaft of the rotation mechanism 267 is connected to the susceptor 217 so that the susceptor 217 is rotated by operating the rotation mechanism 267. A controller 121 to be described later is connected to the rotation mechanism 267 through a coupling unit 266. The coupling unit 266 is provided as a slip-ring mechanism which is electrically connected between a rotation side and a fixed side by a metal brush or the like. Accordingly, rotation of the susceptor 217 is prevented from being interrupted. The controller 121 is constituted to control power supplied to the rotation mechanism 267 so that the susceptor 217 is rotated at a predetermined speed for a predetermined time.

[Heating Unit]

A heater 217b serving as a heating mechanism is integrally embedded in the susceptor 217 to heat the wafer 201. When power is supplied to the heater 217b, the surface of the wafer 201 is heated to a predetermined temperature (for example, approximately room temperature to 1,000° C.). In addition, a temperature sensor is provided in the susceptor 217. The controller 121 to be described later is electrically connected to the heater 217b and the temperature sensor. The controller 121 is constituted to control power supplied to the heater 217b based on temperature information detected by the temperature sensor.

On an upper portion of the process chamber 108, that is, an upper surface of the upper vessel 210, a lamp heating unit 218 that heats the wafer 201 in the process chamber 108 is provided. The lamp heating unit 218 is constituted to irradiate light into the process chamber 108 through a light transmission window 219 provided on the upper surface of the upper vessel 210.

From the lamp heating unit 218, infrared rays having a wavelength of about 0.7 μm to about 250 μm, preferably about 1.3 μm to about 200 μm, and more preferably about 2 μm to about 20 μm are irradiated, or infrared rays having a medium wavelength of most preferably about 2 μm to about 4.5 μm are irradiated. When water or hydrogen peroxide water containing water (H₂O) molecules is used as the process liquid (oxidant solution) in an oxidation process S40 as will be described below, water molecules easily absorb infrared rays having such a wavelength band. As a result, heating efficiency may be improved.

As such a lamp heating unit 218, a Kanthal wire heater having a wavelength of about 2.2 μm as an emission peak wavelength may be used. As the lamp heating unit 218 other than the Kanthal wire heater, a carbon heater, a SiC heater, a lamp using tungsten, a halogen lamp, or the like may be used.

[Supply Unit]

On the upper portion of the process chamber 108, a shower head 236 that supplies a process liquid or a gas into the process chamber 108 is provided. The shower head 236 includes a cap-shaped lid 233, a process liquid inlet portion 234, a gas inlet portion 235, a buffer chamber 237, a shielding plate 240, and a blowout port 239.

The lid 233 is provided hermetically in an opening opened at the upper portion of the upper vessel 210. The shielding plate 240 is provided in the lower portion of the lid 233. A space between the lid 233 and the shielding plate 240 is the buffer chamber 237. The buffer chamber 237 functions as a dispersion space for dispersing the process liquid introduced from the process liquid inlet portion 234. In addition, the buffer chamber also functions as a dispersion space for dispersing a gas introduced from the gas inlet portion 235. The process liquid or the gas which passes through the buffer chamber 237 is supplied into the process chamber 108 from the blowout port 239 of a side portion of the shielding plate 240. In addition, an opening is provided in the lid 233. In the opening of the lid 233, each of the downstream ends of the process liquid inlet portion 234 and the gas inlet portion 235 is hermetically provided. A downstream end of a process liquid supply pipe 220 is connected to the upstream end of the process liquid inlet portion 234 through an O-ring 203b as a sealing member. A downstream end of a gas supply pipe 224 is connected to the upstream end of the gas inlet portion 235 through the O-ring 203b as the sealing member 203b.

[Process Liquid Supply Unit]

In the process liquid supply pipe 220, a process liquid supply source 221 for supplying a process liquid, a liquid flow rate controller 222 serving as a liquid flow rate control device, and a valve 223 that is an opening and closing valve are provided in the stated order from the upstream side.

An oxidant solution such as hydrogen peroxide water or water (H₂O) or pure water is supplied as the process liquid into the process chamber 108 through the liquid flow rate controller 222, the valve 223, the buffer chamber 237, and the blowout port 239. That is, the process liquid is dropped from the process liquid supply pipe 220 to be supplied to the wafer 201.

Here, as the hydrogen peroxide water, hydrogen peroxide (H₂O₂) which is a solid or a liquid at room temperature is used and water (H₂O) is used as a solvent, whereby the hydrogen peroxide water is produced by dissolving the hydrogen peroxide in the water. The concentration of hydrogen peroxide of the hydrogen peroxide water is preferably 1% to 40%. In the present embodiment, the hydrogen peroxide water in which the concentration of hydrogen peroxide is 15% or 30% is preferably used. When the hydrogen peroxide water is used as the oxidant solution, the oxidation process S40 to be described later may be performed at a low temperature and in a short time.

In addition, a solution (silicon-containing material) obtained in such a manner that a silicon material such as perhydro-polysilazane (hereinafter referred to as “PHPS”) is dissolved as the process liquid in a solvent such as water (H₂O) may be supplied from the process liquid supply pipe 220 into the process chamber 108 through the liquid flow rate controller 222, the valve 223, the buffer chamber 237, and the blowout port 239. In addition, as the solvent, an organic solvent such as xylene (C₈H₁₀), toluene (C₆H₅CH₃), dibutyl ether (C₈H₁₈O), or the like may be used. Polysilazane is a material that substitutes for a coating insulating material containing an inorganic or organic component called spin on glass (SOG) which has been conventionally used. Polysilazane is a material obtained by catalytic reaction between dichlorosilane or trichlorosilane and ammonia. When polysilazane is used as a silicon material, a silicon oxide film may be easily formed. In addition, as the silicon material, hexamethyldisilazane (HMDS), hexamethylcyclotrisilazane (HMCTS), polycarbosilazane, polyorganosiloxane, trisilylamine (TSA), or the like may be used rather than polysilazane.

The controller 121 to be described later is electrically connected to the liquid flow rate controller 222 and the valve 223. The controller 121 is constituted to control the degree of opening of the liquid flow rate controller 222 and opening and closing of the valve 223 so that a flow rate of the process liquid supplied into the process chamber 108 becomes a predetermined flow rate at a predetermined timing.

A process liquid supply unit is mainly constituted of the process liquid supply pipe 220, the liquid flow rate controller 222, and the valve 223. In addition, the process liquid supply source 221, the buffer chamber 237, and the blowout port 239 may be included in the process liquid supply unit.

[Gas Supply Unit]

In the gas supply pipe 224, a gas supply source 225 for supplying a gas such as a process gas or an inert gas, a mass flow controller 226 serving as a flow rate control device, and a valve 227 that is an opening and closing valve are provided in the stated order from the upstream side.

A gas such as a process gas or an inert gas is supplied into the process chamber 108 from the gas supply pipe 224 through the mass flow controller 226, the valve 227, the buffer chamber 237, and the blowout port 239. As the process gas, a forming gas obtained by diluting hydrogen (H₂) gas with nitrogen (N₂) gas, or nitrogen gas may be used. As the inert gas, nitrogen gas or a noble gas such as He gas, Ne gas, Ar gas, or the like may be used.

The downstream end of a water supply pipe 228 is connected between the mass flow controller 226 and the valve 227 of the gas supply pipe 224. In the water supply pipe 228, a water supply source 229 for supplying water, a mass flow controller 230 serving as a flow rate control device, and a valve 231 that is an opening and closing valve are provided in the stated order from the upstream side.

Water for bubbling pure water with the nitrogen gas supplied from the gas supply source 225 is supplied from the water supply pipe 228. As the water, water vapor obtained by vaporizing pure water, water produced using hydrogen (H₂) gas and oxygen (O₂) gas, or the like may be used.

The controller 121 to be described later is electrically connected to the mass flow controllers 226 and 230 and the valves 227 and 231. The controller 121 is constituted to control the degree of opening of the mass flow controller 226 and opening and closing of the valve 227 so that a flow rate of the gas supplied into the process chamber 108 becomes a predetermined flow rate at a predetermined timing. In addition, the controller 121 is constituted to control the degree of opening of the mass flow controller 230 and opening and closing of the valve 231 so that a flow rate of water for bubbling pure water with the nitrogen gas becomes a predetermined flow rate at a predetermined timing.

The gas supply unit is mainly constituted of the gas supply pipe 224, the mass flow controller 226, and the valve 227. In addition, the gas supply source 225, the buffer chamber 237, and the blowout port 239 may be included in the gas supply unit. In addition, the water supply unit is constituted of the water supply pipe 228, the mass flow controller 230, and the water supply source 229. In addition, the water supply source 229 may be included in the water supply unit. In addition, the water supply unit may be included in the gas supply unit.

[Exhaust Unit]

An upstream end of a first exhaust pipe 241 for exhausting the atmosphere in a reaction vessel 203 (in the process chamber 108) is connected to the reaction vessel 203. In the first exhaust pipe 241, a pressure sensor 242 serving as a pressure detector (pressure detection unit) for detecting the pressure in the reaction vessel 203, an auto pressure controller (APC) valve 243 serving as a pressure regulator (pressure regulating unit), and a vacuum pump 246a serving as a vacuum exhaust device are provided in the stated order from the upstream direction. The first exhaust pipe 241 is constituted to evacuate the inside of the reaction vessel 203 so that the pressure in the reaction vessel 203 is a predetermined pressure (vacuum degree) by the vacuum pump 246a. In addition, the APC valve 243 is an opening and closing valve that can start and stop evacuation on the inside of the reaction vessel 203 by opening and closing the valve and regulate the pressure by adjusting the degree of opening of the valve.

An upstream end of a second exhaust pipe 244 is connected to the upstream side from the APC valve 243 of the first exhaust pipe 241. In the second exhaust pipe 244, a valve 245 that is an opening and closing valve, a separator 247 for separating a gas exhausted from the reaction vessel 203 into a liquid and a gas, and a vacuum pump 246b serving as a vacuum exhaust device are provided in the stated order from the upstream direction. An upstream end of a third exhaust pipe 248 is connected to the separator 247, and a liquid recovery tank 249 is provided in the third exhaust pipe 248. As the separator 247, a gas chromatograph, or the like may be used.

The exhaust unit is constituted of mainly the first exhaust pipe 241, the liquid recovery tank 249, the pressure sensor 242, the APC valve 243, and the valve 245. In addition, the vacuum pump 246a and the vacuum pump 246b may be included in the exhaust unit.

[Control Unit]

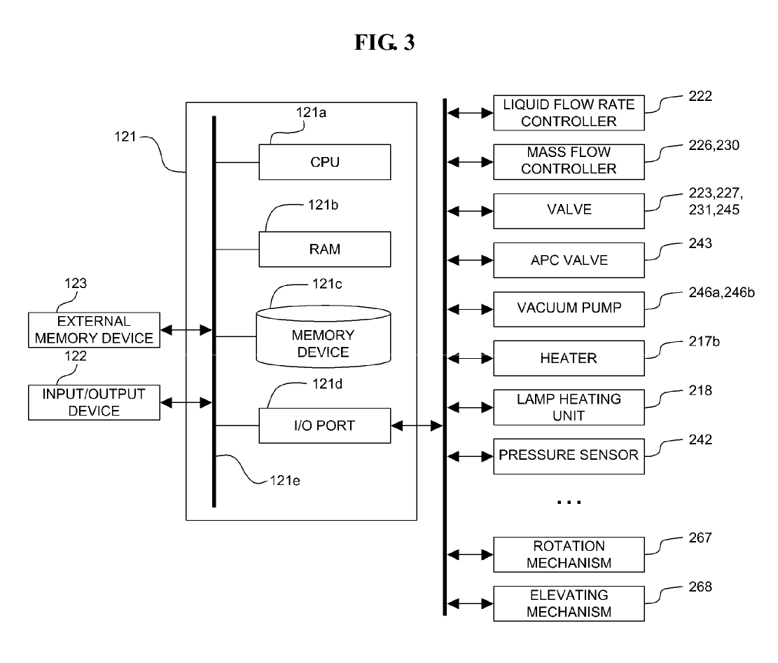

As shown in FIG. 3, the controller 121 that is a control unit (control means) is configured as a computer including a central processing unit (CPU) 121a, a random access memory (RAM) 121b, a memory device 121c, and an I/O port 121d. The RAM 121b, the memory device 121c, and the I/O port 121d are constituted to exchange data with the CPU 121a through an internal bus 121e. A touch panel, a mouse, a keyboard, and an operation terminal, or the like may be connected as an input/output device 122 to the controller 121. In addition, a display or the like may be connected as a display unit to the controller 121.

The memory device 121c is constituted of, for example, a flash memory, a hard disk drive (HDD), a CD-ROM, and the like. A control program for controlling operations of the substrate processing apparatus 100 or a process recipe in which procedures, conditions, and the like of substrate processing to be described later are described may be stored readably in the memory device 121c. In addition, the process recipe is combined to obtain predetermined results by executing, in the controller 121, each procedure in the substrate processing process which will be described later, and functions as a program. Hereinafter, the process recipe or the control program may be collectively and simply referred to as a program. In addition, when the term “program” is used in the present specification, it may include only the process recipe itself, only the control program itself, or both. In addition, the RAM 121b is configured as a memory area (work area) in which programs, data, and the like which are read by the CPU 121a are temporarily held.

The I/O port 121d is connected to the above-described liquid flow rate controller 2222, the mass flow controllers 226 and 230, the valves 223, 227, 231, and 245, the APC valve 243, the pressure sensor 242, the vacuum pumps 246a and 246b, the heater 217b, the lamp heating unit 218, the rotation mechanism 267, the elevating mechanism 268, and the like.

The CPU 121a is constituted to read the control program from the memory device 121c and execute the read control program, and read the process recipe from the memory device 121c in accordance with an input of an operation command from the input/output device 122. The CPU 121a is constituted to control a flow rate regulating operation of a process liquid by the liquid flow rate controller 222 through the single line (I) to follow contents of the read process recipe, a flow rate regulating operation of various gases by the mass flow controllers 226 and 230, an opening and closing operation of the valves 223, 227, and 231, an opening degree regulating operation of the APC valve 243 based on the pressure sensor 242 through the single line (J), an opening and closing operation of the valve 245, start/stop of the vacuum pumps 246a and 246b, a temperature regulating operation of the heater 217b through the signal line (K), a temperature regulating operation of the lamp heating unit 218 through the signal line (L), a rotation speed regulating operation of the rotation mechanism 267 through the signal line (M), a height position regulating operation of the elevating mechanism 268 through the signal line (N), and the like.

In addition, the controller 121 is not limited to being configured as a dedicated computer, and may be configured as a general-purpose computer. For example, the controller 121 according to an embodiment of the present invention may be constituted in such a manner that an external memory device 123 (for example, a magnetic tape, a magnetic disk such as a flexible disk or a hard disk, an optical disc such as CD or DVD, a magneto-optical disc such as an MO, and a semiconductor memory such as a Universal Serial Bus (USB) memory (USB flash drive) or a memory card) which stores the above-described program is prepared and the program is installed in the general-purpose computer using the external memory device 123. In addition, a means for supplying a program to a computer is not limited to a case of supplying the program using the external memory device 123. For example, the program may be supplied using a communication means such as the Internet or a dedicated line without the external memory device 123. In addition, the memory device 121c or the external memory device 123 may be configured as a computer-readable recording medium. Hereinafter, these are collectively and simply referred to as a recording medium. In addition, when the term “recording medium” is used in the present specification, it may include only the memory device 121c itself, only the external memory device 123 itself, or both.

(4) Substrate Processing Process

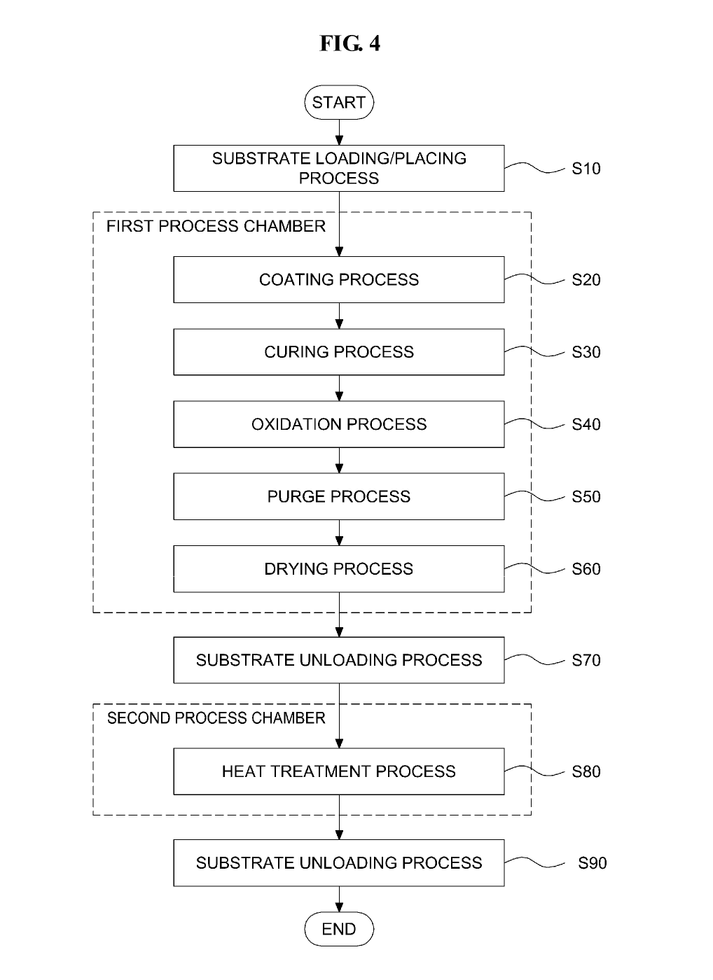

Next, the substrate processing process performed as one process of a manufacturing process of a semiconductor device according to an embodiment of the present invention will be described mainly with reference to FIG. 4. FIG. 4 is a flowchart illustrating the substrate processing process according to the present embodiment. The substrate processing process is performed by the above-described substrate processing apparatus 100. In addition, in the following descriptions, operations of each component constituting the substrate processing apparatus 100 may be controlled by the controller 121 shown in FIG. 3.

A case of using a substrate having an uneven structure that is a minute structure as the wafer 201 will be described herein. The substrate having the minute structure refers to a substrate having a high aspect ratio such as deep grooves (recessed portion) in a vertical direction to a silicon substrate or narrow grooves (recessed portion) in a horizontal direction with a width of about 10 nm to 50 nm or preferably about 10 nm or 20 nm. Such a minute uneven structure is formed by, for example, a gate insulating film, a gate electrode, a minute semiconductor device, and the like.

Hereinafter, an example in which a silicon (Si)-containing film is formed in the groove of the wafer 201 and a silicon oxide film is formed as an insulating film by oxidizing the silicon-containing film using hydrogen peroxide water as an oxidant solution that is a process liquid will be described.

[Loading/Placing Process (S10) of Substrate]

First, the wafer elevating pin 265 passes through the through-hole 217a of the susceptor 217 by lowering the susceptor 217 to a transport position of the wafer 201. As a result, the wafer elevating pin 265 protrudes by a predetermined height from the surface of the susceptor 217. Subsequently, the gate valve 105 is opened, and the wafer 201 is loaded into the process chamber 108 as a first process chamber using the load/unload arm 106. As a result, the wafer 201 is supported in a horizontal posture on the wafer elevating pin 265 that protrudes from the surface of the susceptor 217.

When the wafer 201 is loaded into the process chamber 108, the load/unload arm 106 is retracted to the outside of the process chamber 108, and the inside of the process chamber 108 is sealed by closing the gate valve 105. Next, the susceptor 217 is raised using the elevating mechanism 268. As a result, the wafer 201 is disposed on the upper surface of the susceptor 217. Next, the wafer 201 is raised to a predetermined process position by raising the susceptor 217 to a predetermined position.

In addition, when loading the wafer 201 into the process chamber 108, it is preferable to supply an inert gas such as nitrogen (N₂) gas as a purge gas into the process chamber 108 from the gas supply unit while exhausting the inside of the process chamber 108 by the exhaust unit. That is, it is preferable to open at least one of the APC valve 243 and the valve 245 by operating at least one of the vacuum pump 246a and the vacuum pump 246b, thus opening the valve 227 while exhausting the inside of the process chamber 108 and the nitrogen (N₂) gas is supplied into the process chamber 108 through the buffer chamber 237. Thus, it is possible to prevent invasion of particles into the process chamber 108 or adhesion of particles on the wafer 201. In addition, it is preferable to maintain operation of at least one of the vacuum pump 246a and the vacuum pump 246b until at least the loading/placing process (S10) of the substrate to a substrate unloading process (S70) to be described later is completed.

In addition, by operating the rotation mechanism 267, rotation of the susceptor 217, that is, rotation of the wafer 201, is started. In this instance, a rotation speed of the susceptor 217 is controlled by the controller 121. In addition, rotation of the susceptor 217 is maintained until at least a heat treatment process (S80) to be described later is completed.

[Coating Process (S20)]

Next, a solution (silicon-containing material) obtained in such a manner that a silicon material such as polysilazane (PHPS) or the like is dissolved in a solvent such as xylene (C₈H₁₀) is coated on the wafer 201 by, for example, a spin coating method to fill the grooves (recessed portion) of the wafer 201 with the solution. That is, the valve 223 is opened, and the silicon-containing material that is a process liquid is supplied from the process liquid supply pipe 220 into the process chamber 108 through the buffer chamber 237. In this instance, a flow rate of the silicon-containing material is adjusted by the liquid flow rate controller 222 so that the flow rate of the silicon-containing material is a predetermined flow rate. Thus, a silicon-containing film (PHPS film) is formed on the wafer 201. That is, the silicon-containing film is formed in the grooves of the wafer 201.

In addition, the silicon-containing material is coated on the wafer 201 so that a film thickness of the silicon-containing film formed on the wafer 201 is 100 nm to 700 nm. The film thickness of the silicon-containing film may be adjusted by a molecular weight or viscosity of silicon such as polysilazane, a rotation speed of the wafer 201 (rotation speed of the susceptor 217), or the like.

When a predetermined processing time has elapsed and the silicon-containing film having a predetermined film thickness is formed on the wafer 201, the valve 223 is closed, and supply of the silicon-containing material into the process chamber 108 is stopped.

Here, the silicon-containing film formed on the wafer 201 is made of mainly a silicon material (polysilazane). However, there are cases in which a solvent component contained in the silicon-containing material remains in the silicon-containing film. In addition, impurities other than silicon (Si) such as nitrogen (N) or hydrogen (H) resulting from the silicon material are contained in the silicon-containing film. That is, the silicon-containing film includes at least silazane bonds (Si—N bonds). In addition, in some cases, carbon (C) or other impurities are likely to be contained in the silicon-containing film. That is, in the spin coating method, there are many cases in which a liquid obtained by adding an organic solvent as a solvent to the silicon material such as polysilazane is used as the silicon-containing material. The carbon (C) or the other impurities (that is, elements other than Si and O) resulting from the organic solvent are mixed in the silicon-containing film.

[Hardening Process (S30)]

When a coating process (S20) is completed, supply of a forming gas (for example, a gas obtained by diluting hydrogen gas into nitrogen gas) into the process chamber 108 is started. That is, the valve 227 is opened, and the forming gas that is a process gas is supplied into the process chamber 108 from the gas supply pipe 224 through the buffer chamber 237. In this instance, the flow rate of the process gas is adjusted by the mass flow controller 226 so that the flow rate of the process gas is a predetermined flow rate.

The process chamber 108 is filled with the forming gas, and then the wafer 201 is heated to have a predetermined temperature (for example, 150° C.) by supplying power to at least one of the heater 217b embedded in the susceptor 217 and the lamp heating unit 218. That is, a pre-baking process is performed by heating the wafer 201 under the forming gas atmosphere. Thus, by evaporating a solvent component of the silicon-containing film formed on the wafer 201, the silicon-containing film may be hardened.

When the predetermined processing time has elapsed and the silicon-containing film on the wafer 201 is hardened, power supply to the heater 217b or the lamp heating unit 218 is stopped. Next, the valve 231 is closed, and supply of the forming gas into the process chamber 108 is stopped.

[Oxidation Process (S40)]

When the hardening process (S30) is completed, the inside of the process chamber 108 is adjusted by at least one of the vacuum pump 246a and the vacuum pump 246b and the gas supply unit so that the inside of the process chamber 108 is a pressure equal to or greater than atmospheric pressure (for example, 0.3 MPa). In this instance, the pressure in the process chamber 108 is measured by the pressure sensor 242, and at least one of an opening degree of the APC valve 243 and opening and closing of the valve 245 is subjected to feedback control based on the measured pressure information.

The wafer 201 accommodated in the process chamber 108 is heated by at least one of the heater 217b and the lamp heating unit 218 so that the wafer 201 has a predetermined temperature (for example, 40° C. or more and 100° C. or less, preferably 50° C. or more and 100° C. or less, and more preferably 40° C. or more and 50° C. or less).

When the temperature of the wafer 201 reaches the predetermined temperature (for example, about 50° C.), supply of hydrogen peroxide water as an oxidant solution that is the process liquid into the process chamber 108 is started. That is, the valve 223 is opened, and the hydrogen peroxide water that is the process liquid is supplied into the process chamber 108 from the process liquid supply pipe 220 through the buffer chamber 237. In this instance, the flow rate of the process liquid is adjusted by the liquid flow rate controller 222 so that the flow rate of the process liquid is a predetermined flow rate.

Since the hydrogen peroxide (H₂O₂) water has a simple structure in which hydrogen is bonded to oxygen molecules, the hydrogen peroxide (H₂O₂) water has a characteristic of easily penetrating a low density medium. In addition, when the hydrogen peroxide water is decomposed, hydroxyl radicals (OH*) are produced. The hydroxyl radicals are a kind of active oxygen and are neutral radicals in which oxygen and hydrogen are bonded. The hydroxyl radicals have a strong oxidizing power. Thus, in the present embodiment, the silicon-containing film (PHPS film) on the wafer 201 is oxidized by the hydroxyl radicals produced through decomposition of the hydrogen peroxide water supplied into the process chamber 108, and thus the silicon oxide film is formed. That is, by the oxidizing power of the hydroxyl radicals, silazane bonds (Si—N bonds) or Si—H bonds which the silicon-containing film has are separated. Next, the separated nitrogen (N) or hydrogen (H) is substituted with oxygen (O) contained in the hydroxyl radicals, whereby Si—O bonds of the silicon-containing film are formed. As a result, the silicon-containing film is oxidized to be reformed into the silicon oxide film. In addition, impurities such as nitrogen (N) or hydrogen (H) separated by the hydroxyl radicals are discharged to the outside of the process chamber 108 from the exhaust unit or the like.

In this manner, by supplying the hydrogen peroxide water that is the process liquid into the process chamber 108 under a pressure equal to or greater than atmospheric pressure and reforming the silicon-containing film on the wafer 201 into the silicon oxide film, the film quality of the silicon oxide film may be improved. That is, by pressurizing the inside of the process chamber 108 with the pressure equal to or greater than atmospheric pressure, it is possible for the hydrogen peroxide water to penetrate the silicon-containing film formed on the bottom (deep groove in the groove) of the grooves of the wafer 201. Thus, the silicon-containing film formed on the bottom portion of the grooves of the wafer 201 can be oxidized, thereby improving the film quality of the silicon oxide film. In addition, it is possible to promote reaction between the hydrogen peroxide water and the silicon-containing film.

In addition, by performing an oxidation process at a low temperature of about 40° C. to 100° C. using the hydrogen peroxide water as the oxidant solution, the film quality of the silicon oxide film may be more improved. That is, by performing the oxidation process at a low temperature, it is possible to suppress only the surface portion of the silicon-containing film formed in the grooves having the minute structure of the wafer 201 from being first oxidized. Thus, a more uniform oxidation process may be performed in the grooves included in the wafer 201, and the film quality of the silicon oxide film may be more improved.

In addition, the hydrogen peroxide water acts more actively in a use environment above room temperature of, for example, 40° C. or more and 100° C. or less, and preferably 50° C. or more and 100° C. or less. Thus, the hydrogen peroxide water may be supplied by the silicon-containing film formed on the deep grooves of the wafer 201. In addition, in this temperature range, the oxidizing power of hydrogen peroxide may be sufficiently exerted. Thus, the oxidation process may be performed in a short time. In addition, in the use environment of 40° C. or more and 50° C. or less, uniformity of the process on the wafer 201 may be more improved.

When a predetermined processing time has elapsed, the valve 233 is closed, and supply of the hydrogen peroxide water as the process liquid into the process chamber 108 is stopped.

[Purge Process (S50)]

After the oxidation process (S40) is completed, at least one of the APC valve 243 and the valve 245 is opened. That is, the inside of the process chamber 108 is exhausted by the exhaust unit, thereby discharging residues such as hydrogen peroxide water which remain in the process chamber 108. In this instance, the valve 237 is opened, and the N₂ gas that is the inert gas is supplied as the purge gas into the process chamber 108, and therefore discharge of the residues from the inside of the process chamber 108 may be promoted.

Next, by controlling at least one of an opening degree of the APC valve 243 and opening and closing of the valve 245, the pressure in the process chamber 108 is returned to atmospheric pressure. Specifically, the valve 237 is opened, and at least one of the opening degree of the APC valve 243 of the exhaust unit and the opening and closing of the valve 245 is controlled based on the pressure sensor 242 while the N₂ gas that is the inert gas is supplied into the process chamber 108, thereby lowering the pressure in the process chamber 108 to atmospheric pressure.

[Drying Process (S60)]

When the oxidation process (S40) is completed, a rotation speed of the susceptor 217, that is, a rotation speed of the wafer 201, is set to a predetermined speed by adjusting supply power to the rotation mechanism 267. When the rotation speed of the wafer 201 reaches the predetermined speed, the valve 223 is opened and pure water is supplied as the process liquid into the process chamber 108 from the process liquid supply pipe 220 through the buffer chamber 237. In this manner, by supplying pure water into the process chamber 108 while rotating the wafer 201, a centrifugal force is exerted on water on the wafer 201 to remove the water from the wafer 201, thereby drying the wafer 201. In addition, by supplying pure water into the process chamber 108, hydrogen peroxide in the process chamber 108 or by-products generated in the oxidation process (S40) and the like can be removed from the wafer 201.

In addition, drying of the wafer 201 may be performed by supplying, for example, alcohol into the process chamber 108 while rotating the wafer 201. That is, the valve 223 may be opened, and alcohol may be supplied into the process chamber 108 from the process liquid supply pipe 220 through the buffer chamber 237. That is, by substituting water on the wafer 201 with alcohol, the water on the wafer 201 may be removed, and then alcohol on the wafer 201 may be removed, thereby drying the wafer 201. In addition, as the alcohol, for example, isopropyl alcohol (IPA) or the like may be used. In this instance, the wafer 201 may be heated to an appropriate temperature by a heating element such as the heater 217b, the lamp heating unit 218, a resistance heating heater, or the like while rotating the wafer 201. Thus, by promoting removal of alcohol from the wafer 201, drying of the wafer 201 may be promoted. In addition, alcohol may be supplied into the process chamber 108 in a gas (vapor) state. That is, the valve 227 may be opened, and alcohol in the gas state may be supplied as the process gas into the process chamber 108 from the gas supply pipe 224.

In addition, drying of the wafer 201 may be performed in a method such as blow drying performed by supplying the nitrogen gas into the process chamber 108 or rotation spin drying performed by rotating the wafer 201.

[Substrate Unloading Process (S70)]

Next, by lowering the susceptor 217 to the transport position of the wafer 201, the wafer 201 is supported on the wafer elevating pins 265 which protrude from the surface of the susceptor 217. Next, the gate valve 105 is opened, and the wafer 201 is unloaded from the process chamber 108 to the outside using the load/unload arm 106. The wafer 201 which has been unloaded using the load/unload arm 106 is loaded into the process chamber 109 serving as a second process chamber which is different from the process chamber 108 serving as the first process chamber.

[Heat Treatment Process (S80)]

When the drying process (S60) is completed, the wafer 201 which has been loaded into the process chamber 109 serving as the second process chamber to be accommodated is heated by at least one of the heater 217b and the lamp heating unit 218 so that the temperature of the wafer 201 becomes a predetermined temperature (for example, about 250° C.), and a baking process (annealing process) is performed.

In addition, when the wafer 201 is loaded into the process chamber 109, it is preferable that an inert gas such as nitrogen (N₂) gas be supplied as the purge gas into the process chamber 108 from the gas supply unit while exhausting the inside of the process chamber 109 by the exhaust unit. Thus, it is possible to prevent invasion of particles into the process chamber 109 or adhesion of particles on the wafer 201. In addition, operation of at least one of the vacuum pump 246a and the vacuum pump 246b may be maintained until the substrate unloading process (S90).

When the temperature of the wafer 201 reaches the predetermined temperature, supply of the process gas into the process chamber 109 is started while exhausting the process gas from the exhaust unit. That is, the valve 227 and the valve 231 are opened, and the process gas is supplied into the process chamber 109 from the process liquid supply pipe 220 through the buffer chamber 237. As the process gas, the nitrogen gas containing water such as a gas obtained by bubbling pure water with the nitrogen gas may be used. In addition, as the process gas, a gas obtained by bubbling water produced using hydrogen (H₂) gas and oxygen (O₂) gas with the nitrogen gas may be used.

When supply of the nitrogen gas containing water as the process gas into the process chamber 109 is started, the wafer 201 is further heated. That is, the wafer 201 is heated by at least one of the heater 217b and the lamp heating unit 218 so that the temperature of the wafer 201 becomes a predetermined temperature (for example, about 400° C.), while supplying the process gas into the process chamber 109. Thus, the wafer 201 can be heated while evaporating the wafer contained in the process gas. That is, the wafer 201 may be heated in a steam atmosphere.

Here, when the above-described oxidation process (S40) is completed, the silicon-containing film (silicon oxide film) on the wafer 201 on which the heat treatment process (S80) is performed contains OH. That is, when performing the oxidation process using the hydrogen peroxide water as the process liquid in the oxidation process (S40), OH is adsorbed on the surface of the silicon-containing film (silicon oxide film). In addition, OH is captured in the silicon-containing film (silicon oxide film). In addition, OH is contained in the silicon-containing film (silicon oxide film) in a state of OH, a state of H₂O, or a state of H₂O₂.

Therefore, gasified hydroxyl radicals (OH*) may be produced in the process chamber 108. Impurities contained in the silicon-containing film (silicon oxide film) such as nitrogen (N), hydrogen (H), carbon (C), and the like which have not been completely removed in the above-described oxidation process (S40) may be removed by the hydroxyl radicals. That is, it is possible to oxidize components which have not been completely oxidized in the above-described oxidation process (S40). Thus, it is possible to improve the film quality of the silicon oxide film more. As a result, it is possible to improve density of the silicon oxide film on the wafer 201.

When the temperature of the wafer 201 reaches the predetermined temperature (for example, about 400° C.), the valve 231 is closed, and supply of water into the process chamber 109 is stopped. In this instance, the valve 227 and at least one of the APC valve 243 and the valve 245 are kept opened. That is, by continuously performing exhaust of the inside of the process chamber 109 by the exhaust unit and supply of the nitrogen gas into the process chamber 108, water is discharged (removed) from the process chamber 108.

When water is discharged (removed) from the process chamber 109, the wafer 201 is further heated by at least one of the heater 217b and the lamp heating unit 218 so that the temperature of the wafer 201 becomes a predetermined temperature (for example, 450° C.). That is, the wafer 201 is further heated in the process chamber 109 under the nitrogen atmosphere without water. When the temperature of the wafer 201 reaches the predetermined temperature (for example, 450° C.), the wafer 201 is continuously heated for a predetermined time (for example, for 30 minutes) while maintaining the temperature of the wafer 201. When the predetermined time has elapsed, power supply to the heater 217b or the lamp heating unit 218 is stopped. Next, the wafer 201 is subjected to natural cooling so that the temperature of the wafer 201 is lowered. In this manner, by heating the wafer 201 in the process chamber 109 under the nitrogen atmosphere without water for a predetermined time, it is possible to remove OH which is adsorbed on the surface of the silicon oxide film formed on the wafer 201 or captured in the silicon oxide film.

[Substrate Unloading Process (S90)]

Next, by lowering the susceptor 217 to the transport position of the wafer 201, the wafer 201 is supported on the wafer elevating pins 265 which protrude from the surface of the susceptor 217. Next, the gate valve 105 is opened, the wafer 201 is unloaded from the process chamber 109 to the outside using the load/unload arm 106, and the substrate processing process according to the present embodiment is completed.

(5) Effects of Present Embodiment

According to the present embodiment, one or a plurality of effects shown below may be obtained.

(a) According to the present embodiment, the substrate processing process includes the oxidation process (S40) in which the silicon-containing film of the wafer 201 on which the silicon-containing film is formed is oxidized by supplying the process liquid from the process liquid supply unit into the process chamber 108 under the pressure equal to or greater than atmospheric pressure. Thus, the film quality of the silicon oxide film formed by oxidizing the silicon-containing film may be improved. That is, by performing an oxidation process of the silicon-containing film in the process chamber 108 under the pressure equal to or greater than atmospheric pressure, the hydrogen peroxide water is supplied and penetrates to the silicon-containing film formed on the bottom portion (deep grooves) of the grooves of the wafer 201 having a minute structure. Thus, even the silicon-containing film formed on the bottom portion of the grooves of the wafer 201 may be oxidized, thereby performing a uniform process on the grooves. In addition, a minute uneven structure having a processing dimension of 50 nm or less is formed, whereby a uniform process may be performed even in the wafer 201 having an increased surface area.

In addition, by performing the oxidation process in the process chamber 108 under the pressure equal to or greater than atmospheric pressure, it is possible to promote reaction between the process liquid and the silicon-containing film. Thus, the processing time can be shortened.

(b) According to the present embodiment, the process liquid contains hydrogen peroxide. Thus, by oxidizing the silicon-containing film on the wafer 201 at a low temperature and in a short time, the silicon-containing film may be reformed into the silicon oxide film. Thus, the film quality of the silicon oxide film may be more improved.

That is, by performing the oxidation process at the low temperature, it is possible to prevent only the surface portion of the silicon-containing film from being first oxidized. Thus, the uniform oxidation process may be performed by the wafer 201, and the film quality of the silicon oxide film may be more improved. When performing the oxidation process at a high temperature, there is a case in which only the surface portion of the silicon-containing film is first oxidized. In addition, by performing the oxidation process at the low temperature, a heat load to the silicon oxide film (semiconductor device) may be reduced. That is, it is possible to reform the silicon-containing film into the silicon oxide film without changing characteristics of the semiconductor device such as a gate oxide film or a gate electrode formed on the wafer 201.

In addition, by performing the oxidation process at the low temperature, the hydrogen peroxide water may be more activated. Thus, it is possible to further supply the hydrogen peroxide water to the lower portion of the silicon-containing film on the wafer 201, and improve the film quality of the silicon oxide film more. In addition, an oxidizing power of hydrogen peroxide may be sufficiently exerted by performing the oxidation process at the low temperature. Thus, the oxidation process may be performed in a short time. Thus, it is possible to improve a processing throughput (manufacturing throughput of the wafer 201) of the substrate processing apparatus 100.

(c) According to the embodiment, the silicon-containing film contains polysilazane. Thus, the silicon-containing film formed on the wafer 201 having a minute uneven structure may be more easily oxidized to be reformed into the silicon oxide film.

In addition, the silicon-containing film may be formed into the silicon oxide film having Si—O bonds which does not contain a large amount of NH— as a main backbone. The silicon oxide film is different from the silicon oxide film formed as the conventional organic SOG, and has high heat resistance.

(d) According to the present embodiment, the substrate processing process includes the drying process (S60) in which the wafer 201 is dried after the oxidation process (S40) is completed. Thus, hydrogen peroxide in the process chamber 108 or by-products generated in the oxidation process (S40) may be removed from the wafer 201.

(e) According to the present embodiment, the substrate processing process includes the heat treatment process (S80) of heating the wafer 201 after the oxidation process (S40) is completed. Thus, it is possible to oxidize components of the silicon-containing film which have not been completely oxidized in the oxidation process (S40). That is, by performing the heat treatment process (S80), impurities in the silicon-containing film in the deepest portion of the grooves of the wafer 201 such as nitrogen or hydrogen, or other impurities may be removed. Thus, it is possible to improve the film quality of the silicon oxide film more. That is, it is possible to sufficiently perform oxidation, densification, and hardening of the silicon-containing film. As a result, the silicon oxide film may obtain superior wafer etching rate (WER) characteristics as an insulating film. In addition, since WER highly depends on a final annealing temperature, the WER characteristics may be improved with an increase in the temperature.

(f) According to the present embodiment, the silicon-containing film contained in the wafer 201 on which the heat treatment process (S80) is performed contains OH. Thus, gasified hydroxyl radicals (OH*) may be produced in the process chamber 108. Impurities contained in the silicon-containing film (silicon oxide film) such as nitrogen (N), hydrogen (H), carbon (C), and the like which have not been completely removed in the above-described oxidation process (S40) may be removed by the hydroxyl radicals.

(g) According to the present embodiment, in the heat treatment process (S80), the wafer 201 in the process chamber 108 is heated by at least one of the heater 217b and the lamp heating unit 218 while water (for example, a nitrogen gas containing water) is supplied into the process chamber 108. When the temperature of the wafer 201 reaches a predetermined temperature, supply of water into the process chamber 108 is stopped and water is removed from the process chamber 108. When removing water from the process chamber 108, the wafer 201 is heated to the predetermined temperature for a predetermined time by at least one of the heater 217b and the lamp heating unit 218. In this manner, by heating the wafer 201 in the process chamber 108 under the atmosphere without water for a predetermined time, it is possible to remove OH which has been adsorbed on the surface of the silicon oxide film formed on the wafer 201 or captured in the silicon oxide film. Thus, it is possible to improve the film quality of the silicon oxide film more.

(h) According to the present embodiment, the lamp heating unit 218 for irradiating infrared rays having a predetermined wavelength is used as the heating unit. Thus, it is possible to efficiently heat water molecules, and improve heating efficiency of the wafer 201.

(i) According to the present embodiment, the coating process (S20), the hardening process (S30), the oxidation process (S40), and the drying process (S60) are performed in the same process chamber 108, and the heat treatment process (S80) is performed in the process chamber 109 different from the process chamber 108. Thus, it is possible to improve a processing throughput in the substrate processing apparatus 100 including a plurality of process chambers (for example, process chambers 108 and 109). That is, the heat treatment process (S80) has a longer processing time than the coating process (S20), the oxidation process (S40), and the drying process (S60). In this manner, by performing the processes different from the heat treatment process (S80) having the long processing time in the different process chamber, the processing times in the process chambers 108 and 109 may be set as approximately the same time. In addition, when a plurality of wafers 201 are consecutively processed using the substrate processing apparatus 100 including the plurality of process chambers, the processing time in each process chamber is almost the same, and therefore a parameter such as a waiting time of the wafer 201 or the like need not be considered, and transport management of the plurality of pieces of wafer 201 may be facilitated. In addition, the transport process of the wafer 201 may be simplified.

In addition, different process chambers are used in a process performed by supplying the process liquid into the process chamber such as in the coating process (S20), the oxidation process (S40), and the drying process (S60) and a process performed by supplying a gas into the process chamber such as in the heat treatment process (S80), and therefore it is possible to prevent reaction between a solvent gas of the silicon material such as polysilazane or the like which is produced at the time of heating or a hydrogen peroxide water gas and vapor.

In addition, by performing the coating process (S20), the hardening process (S30), the oxidation process (S40), and the drying process (S60) in the same process chamber 108, a waiting time between the coating process (S20) and the oxidation process (S40), that is, a lead time, may be shortened. Thus, it is possible to improve the processing throughput of the substrate processing apparatus 100. In addition, it is possible to suppress the silicon material such as polysilazane from absorbing water in the air. That is, it is possible to suppress a reaction between the silicon-containing film formed immediately after coating the silicon-containing material on the wafer 201 and water in the air. Thus, it is possible to suppress natural oxidation of the silicon-containing film. As a result, a process having excellent reproducibility for each lot may be performed.

In addition, the process is performed in the same housing, and therefore it is possible to prevent contact with an unexpected material during manufacturing. That is, it is possible to suppress adsorption of siloxanes in clean room environments of semiconductor device manufacturing plants or adsorption of chemical components, or unexpected environmental effects such as electrification or the like.

### Other Embodiments of the Present Invention

Embodiments of the present invention have been described above in detail, but the present invention is not limited thereto, and various modifications are possible without departing from the scope of the invention.

In the above-described embodiments, the oxidation process (S40) is performed in the process chamber 108 under the pressure (for example, 0.3 MPa) higher than atmospheric pressure, but the present invention is not limited thereto. That is, the oxidation process (S40) may be performed in a high pressure in which the process liquid serving as the oxidant solution can penetrate the silicon-containing film on the wafer 201, or performed in the process chamber 108 in the state of atmospheric pressure. Thus, as the process chamber in which the oxidation process (S40) is performed, for example, the conventional batch type cleaning apparatus or a nozzle injection type cleaning apparatus of a single wafer may be used, thereby reducing the processing time required for pressurization and depressurization.

In the above-described embodiments, the nitrogen gas containing water is used as the process gas in the heat treatment process (S80), but the present invention is not limited thereto. That is, when the temperature of the wafer 201 accommodated in the process chamber 108 reaches a predetermined temperature (for example, about 250° C.), the heat treatment may be performed by supplying the nitrogen (N₂) gas not containing water as the process gas into the process chamber 108. This is effective when the silicon-containing film (silicon oxide film) of the wafer 201 contains sufficient water (OH) in the oxidation process (S40). Thus, it is possible to reduce the processing time of the heat treatment process (S80) more.

In addition, the heat treatment process (S80) may be performed while supplying an oxygen-containing gas into the process chamber 108. As the oxygen-containing gas, for example, oxygen (O₂) gas, vapor (H₂O), ozone (O₃) gas, nitrous oxide (NO) gas, nitrogen oxide (NO₂), or the like may be used.

In the above-described embodiments, a case in which the heater 217b and the lamp heating unit 218 are provided as the heating unit has been described, but the present invention is not limited thereto. That is, at least one of the heater 217b and the lamp heating unit 218 may be provided. In addition, other than these, a microwave source or the like may be provided as the heating unit.

In addition, an ultraviolet radiating unit for radiating ultraviolet rays to the wafer 201 may be provided in the process chamber (for example, process chamber 109) in which the heat treatment process (S80). Thus, a denser oxide film may be formed. In the process chamber in which the ultraviolet radiating unit is performed, for example, the following process is performed. First, the wafer 201 is heated to a predetermined temperature (for example, 400° C.) by the heater 217b. When the temperature of the wafer 201 reaches the predetermined temperature, the inside of the process chamber 109 is set to a depressurization state (vacuum state) of the nitrogen atmosphere, and ultraviolet rays are radiated to the wafer 201 from the ultraviolet radiating unit. Bonds between molecules of the silicon oxide film formed on the wafer 201 in the oxidation process (S40), that is, Si—O bonds, are separated by the ultraviolet rays. At the same time, the silicon (Si) component and the oxygen (O) component which are separated by the ultraviolet rays by the heating and vacuum process of the wafer 201 are re-bonded with adjacent molecules. Thus, unnecessary water may be separated from the silicon oxide film.

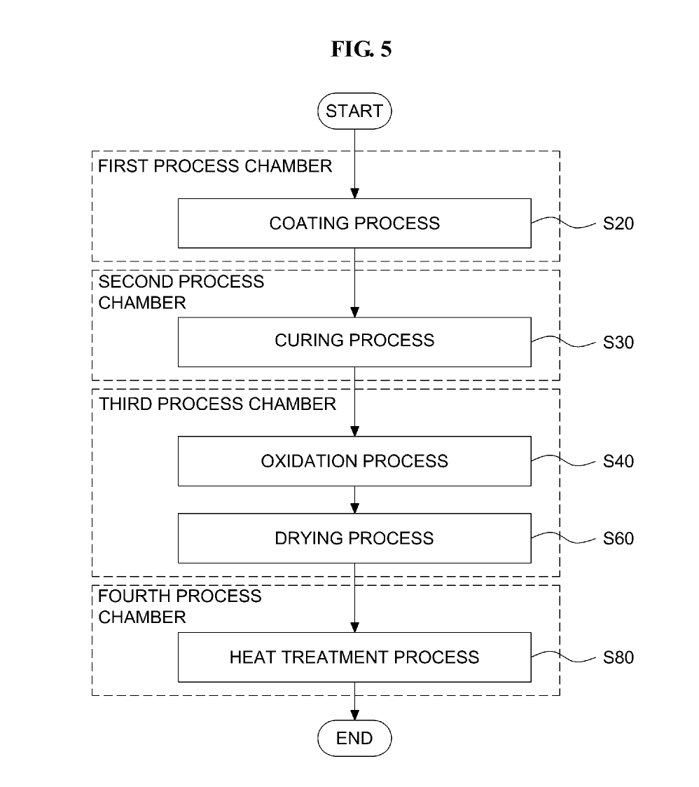

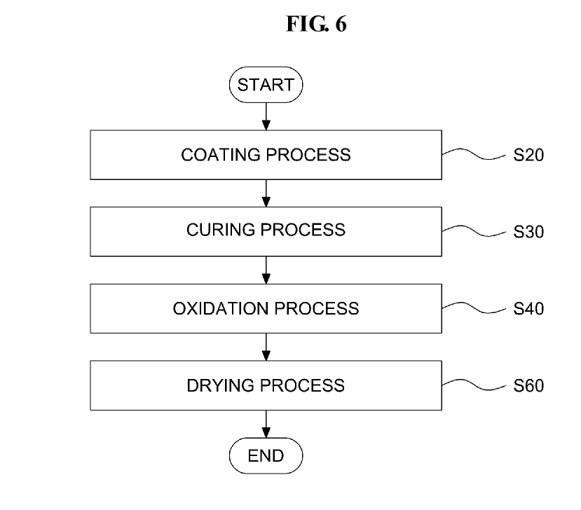

In the above-described embodiments, the coating process (S20), the hardening process (S30), the oxidation process (S40), and the drying process (S60) are performed in the process chamber 108, and the heat treatment process (S80) is performed in the process chamber 109 different from the process chamber 108, but the present invention is not limited thereto. That is, as shown in FIG. 5, the coating process (S20) may be performed in a coating process chamber serving as the first process chamber, the hardening process (S30) may be performed in a pre-baking process chamber serving as the second process chamber, the oxidation process (S40) and the drying process (S60) may be performed in an oxidation/drying process chamber serving as the third process chamber, and the heat treatment process (S80) may be performed in a heat treatment process chamber (baking process chamber) serving as the fourth process chamber. In addition, in FIG. 5, the substrate loading/placing process (S10), the purge process (S50), the substrate loading process (S70), and the substrate unloading process (S90) are not illustrated. However, these processes may be appropriately performed as necessary (in the same manner as in FIGS. 6 to 11).

In addition, each of the coating process (S20), the hardening process (S30), the oxidation process (S40), the drying process (S60), and the heat treatment process (S80) may be performed in a different process chamber. In this manner, by performing each process in the different process chamber, an adjustment time of the atmosphere in the process chamber in which each process is performed may be shortened, thereby improving the processing throughput of the substrate processing apparatus 100. In particular, the process chamber in which the coating process (S20) is performed and the process chamber in which the oxidation process (S40) and the drying process (S60) are performed are different from each other, and therefore it is possible to suppress a reaction between the solvent contained in the silicon-containing material and hydrogen peroxide water or water.

In addition, the coating process (S20), the hardening process (S30), the oxidation process (S40), the drying process (S60), and the heat treatment process (S80) may be performed in the same process chamber 108.

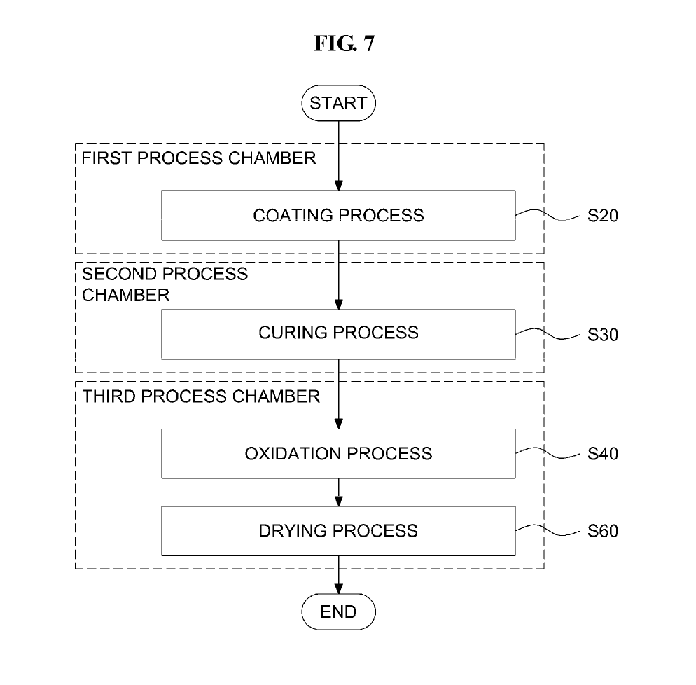

In the above-described embodiments, the heat treatment process (S80) is performed after the drying process (S60), but the present invention is not limited thereto. That is, as shown in FIGS. 6 and 7, the heat treatment process (S80) may not be performed. In this manner, even when the heat treatment process is not performed, the silicon oxide film may be formed on the wafer 201, and a heat load of the semiconductor device formed on the wafer 201 may be reduced. That is, when the semiconductor device such as the gate oxide film or the gate electrode is formed on the wafer 201, it is possible to suppress corruption of characteristics of these elements. In addition, even when the heat treatment process (S80) is not performed, each of the coating process (S20), the hardening process (S30), the oxidation process (S40), and the drying process (S60) may be performed in a different process chamber as shown in FIG. 6. In addition, as shown in FIG. 7, the oxidation process (S40) and the drying process (S60) may be performed in the same process chamber. That is, the coating process (S20) may be performed in the coating process chamber as the first process chamber, the hardening processing (S30) may be performed in the pre-baking process chamber as the second process chamber, and the oxidation process (S40) and the drying process (S60) may be performed in the oxidation/drying process chamber as the third process chamber.

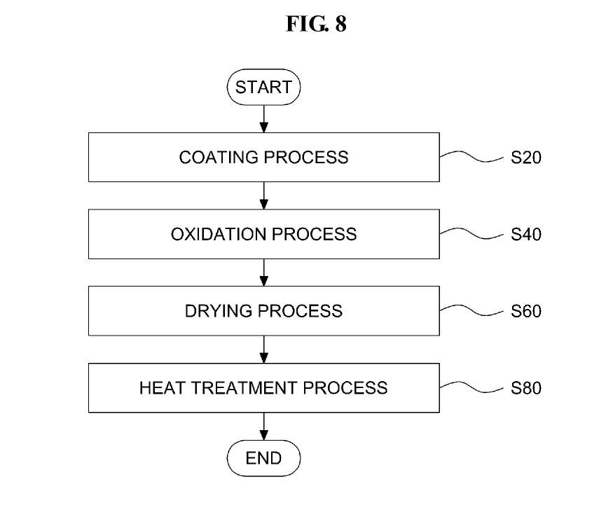

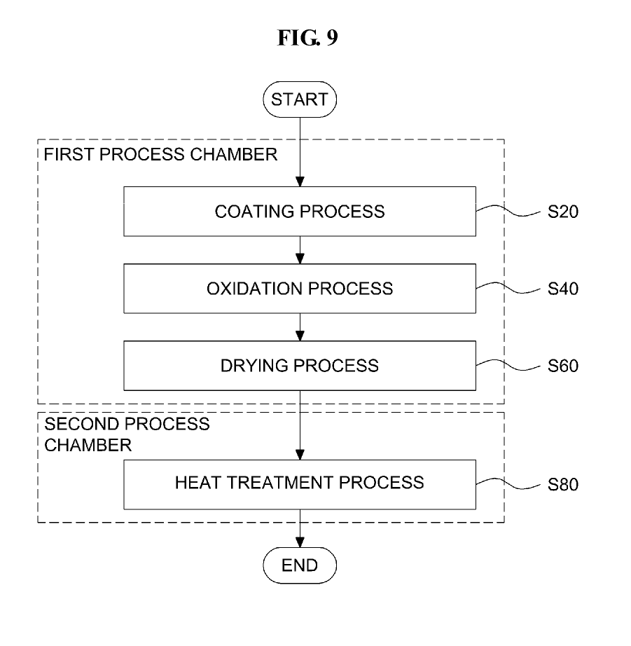

In the above-described embodiments, the hardening process (S30) is performed after the coating process (S20), but the present invention is not limited thereto. For example, as shown in FIGS. 8 and 9, the hardening process (S30) may not be performed. Thus, it is possible to simplify the substrate processing process, thereby improving the processing throughput. In this instance, as shown in FIG. 8, each of the coating process (S20), the oxidation process (S40), the drying process (S60), and the heat treatment process (S80) may be performed in a different process chamber. In addition, for example, as shown in FIG. 9, the coating process (S20), the oxidation process (S40), and the drying process (S60) may be performed in the same process chamber, and the heat treatment process (S80) may be performed in the process chamber different from: the process chamber in which the coating process (S20), the oxidation process (S40), and the drying process (S60) are performed. That is, the coating process (S20), the oxidation process (S40), and the drying process (S60) may be performed in the coating process chamber serving as the first process chamber, and the heat treatment process (S80) may be performed in the baking process chamber serving as the second process chamber.

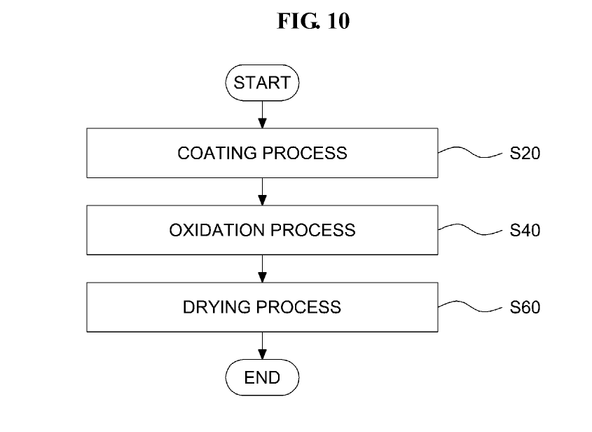

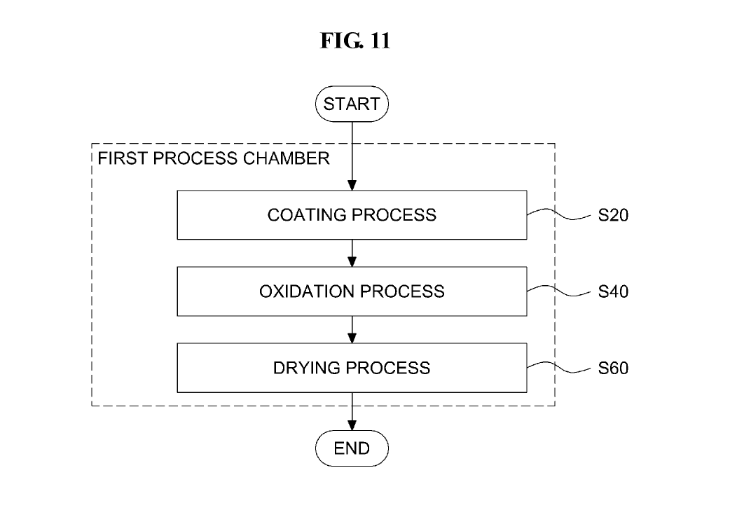

In addition, as shown in FIGS. 10 and 11, the hardening process (S30) and the heat treatment process (S80) may be omitted. In this case, as shown in FIG. 10, each of the coating process (S20), the oxidation process (S40), and the drying process (S60) may be performed in a different process chamber, and as shown in FIG. 11, the coating process (S20), the oxidation process (S40), the drying process (S60) may be performed in the same process chamber (for example, the coating process chamber serving as the first process chamber).

A disposition example of the process chamber in which each process is performed when the substrate processing apparatus 100 including six process chambers 108 to 113 shown in FIG. 1 is used is illustrated.

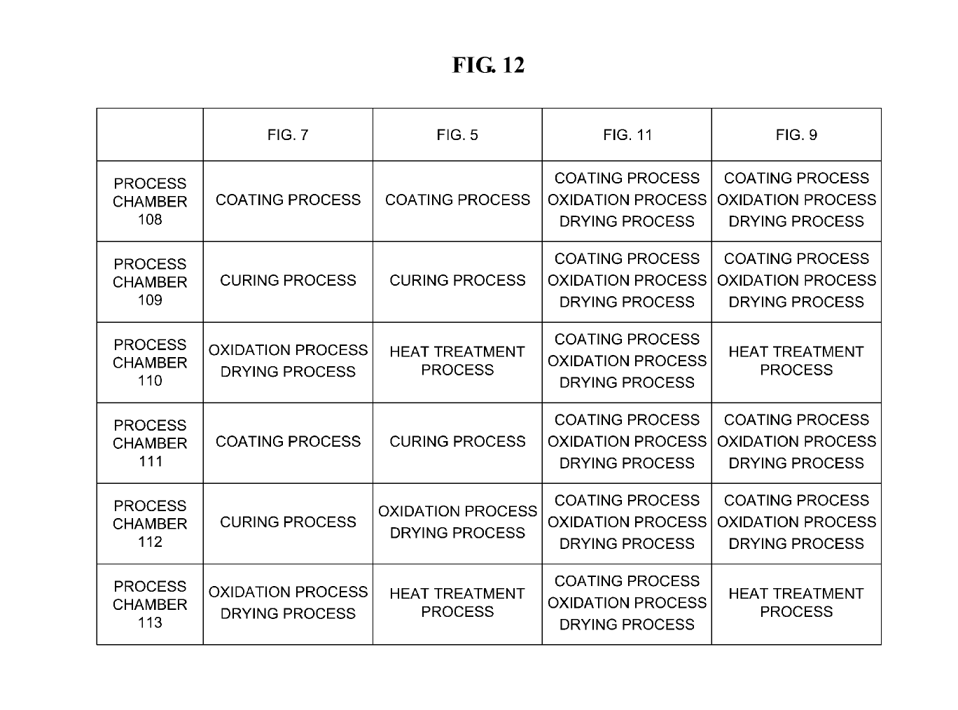

For example, as shown in FIG. 5, when the coating process (S20) is performed in the coating process chamber, the hardening process (S30) is performed in the pre-baking process chamber, the oxidation process (S40) and the drying process (S60) are performed in the oxidation/drying process chamber, and the heat treatment process (S80) is performed in the heat treatment process chamber (baking process chamber), the process chamber 108 may be used as the coating process chamber, the process chambers 109 and 111 may be used as the pre-baking process chamber, the process chamber 112 may be used as the oxidation/drying process chamber, and the process chambers 110 and 113 may be used as the baking process chamber, as shown in FIG. 12.

In addition, as shown in FIG. 7, when the coating process (S20) is performed in the coating process chamber, the hardening process (S30) is performed in the pre-baking process chamber, and the oxidation process (S40) and the drying process (S60) are performed in the oxidation/drying process chamber, the process chambers 108 and 111 may be used as the coating process chamber, the process chambers 109 and 112 may be used as the pre-baking process chamber, and the process chambers 110 and 113 may be used as the oxidation/drying process chamber, as shown in FIG. 12.

In addition, as shown in FIG. 9, when the coating process (S20), the oxidation process (S40), and the drying process (S60) are performed in the coating process chamber, and the heat treatment process (S80) is performed in the baking process chamber, the process chambers 108, 109, 111, and 112 may be used as the coating process chamber, and the process chambers 110 and 113 may be used as the baking process chamber, as shown in FIG. 12.

In addition, as shown in FIG. 11, when the coating process (S20), the oxidation process (S40), and the drying process (S60) are performed in the coating process chamber, the process chambers 108 to 113 may be used as the coating process chamber as shown in FIG. 12.

In the above-described embodiments, the hydrogen peroxide water is dropped from the process liquid supply pipe 220 and supplied to the wafer 200 in the oxidation process (S40), but the present invention is not limited thereto. For example, in the oxidation process (S40), a gas obtained by evaporating the hydrogen peroxide water may be supplied into the process chamber 108 to perform the oxidation process. Thus, simultaneously processing the plurality of wafers 201 may be facilitated.

In addition, in the process chamber in which the oxidation process (S40) is performed, a liquid chemical tank for storing the hydrogen peroxide water may be provided in the process chamber in which the oxidation process (S40) is performed. That is, by storing the hydrogen peroxide water in advance in the liquid chemical tank provided in the process chamber and immersing the wafer 201 containing the silicon-containing film in the liquid chemical tank filled with the hydrogen peroxide water, the oxidation process may be performed. For example, by filling the liquid chemical tank with hydrogen peroxide having a concentration of 30% or more and the hydrogen peroxide water having a liquid temperature of 50° C., and by immersing the wafer 201 for 30 minutes, the oxidation process may be performed. In this instance, the inside of the process chamber in which the liquid chemical tank is provided may be pressurized and adjusted to a pressure (for example, 0.3 MPa) higher than atmospheric pressure. In addition, the pressure of the inside of the process chamber in which the liquid chemical tank is provided may be adjusted to become an atmospheric pressure state.

In addition, in the above-described embodiments, a case of containing polysilazane as the silicon-containing film has been described, but the present invention is not limited. That is, a film that can be oxidized using an oxidant solution such as hydrogen peroxide water other than the silicon-containing film may be formed on the wafer 201. For example, a plasma-polymerized film of trisilylamine (TSA) or ammonia may be used.

In the above-described embodiments, a polysilazane film is formed as the silicon-containing film on the wafer 201 by coating a solution containing polysilazane on the wafer 201, but the present invention is not limited thereto. That is, the wafer 201 on which the silicon-containing film such as the polysilazane film is formed in advance may be used as the wafer 201. The silicon-containing film formed on the wafer 201 in advance may be formed through a chemical vapor deposition (CVD) method or an atomic layer deposition (ALD) method using a silicon (Si) material such as monosilane (SiH₄) gas or TSA gas.

In addition, in the above-described embodiments, a case in which transport of the wafer 201 to each process chamber (108 to 113) included in the substrate processing apparatus 100 is performed by the load/unload arm 106 serving as a transport robot has been described, but the present invention is not limited thereto. For example, each process chamber 108 to 113 included in the substrate processing apparatus 100 may be connected in series to a belt conveyor, and the wafer 201 may be transported to each process chamber 108 to 113 by the belt conveyor.

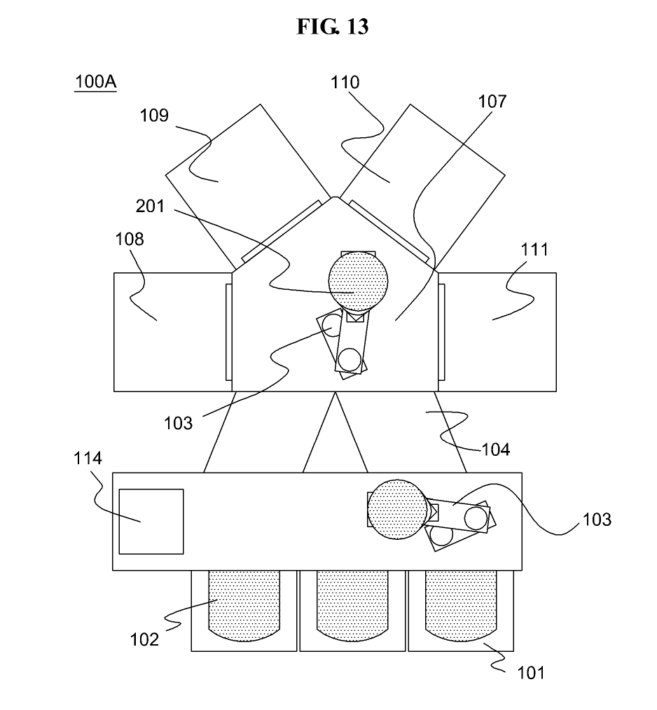

In addition, the present invention is not limited to the substrate processing apparatus shown in FIG. 1. That is, as shown in FIG. 13, a cluster type substrate processing apparatus 100A may be used. In the substrate processing apparatus 100A shown in FIG. 13, four process chambers 108 to 111 may be provided as the process chamber. In addition, in the substrate process apparatus 100A, a notch alignment device 114 is provided as a correction device for performing position correction of the wafer 201. The notch alignment device 114 is constituted to perform a crystal direction of the wafer 201, position alignment, or the like using the notch of the wafer 201. In addition, instead of the notch alignment device 114, an orientation flat alignment device may be provided.

In the above-described embodiments, a single wafer type substrate processing apparatus including the process chamber for processing one sheet of the wafer 201 in a single process chamber has been described, but the present invention is not limited. That is, a multi-wafer type substrate processing apparatus including the process chamber in which a plurality of wafers 201 are placed in the susceptor 217 to be processed in a single process chamber may be used. In addition, a substrate processing apparatus which aligns the plurality of wafers 201 in multiple stages in a vertical direction in a horizontal posture or in a state in which the centers of the plurality of wafers 201 are aligned with each other to hold the wafers 201 by the substrate support mechanism, and includes a vertical process chamber in which a substrate process is performed may be used. When using the batch type substrate processing apparatus that processes the plurality of wafers 201 at once, the processing throughput of the wafers 201 may be improved.

In addition, the inside of the process chamber 108 may be divided into a plurality of processing regions. That is, the above-described processes may be performed in each of the processing regions. In this instance, a rotation table (susceptor) in which the plurality of wafers 201 can be placed in a horizontal direction may be provided in the process chamber 108. The rotation table is rotated such that the wafers 201 pass through each processing region provided in the process chamber 108. Thus, the above-described processes may be performed on the wafers 201.

In addition, in the above-described embodiments, the substrate having a minute uneven structure has been used as the wafer 201, but the present invention is not limited thereto. For example, a substrate on which a semiconductor device pattern is formed as the wafer 201, or a substrate on which a gate oxide film or a gate electrode is formed may be used. By performing the oxidation process at the same low temperature on the substrate, it is possible to process the substrate without corruption of film characteristics of a film formed on the substrate in advance.

In the above-described embodiments, the process of forming the silicon oxide film as the insulating body in the minute groove (recessed portion) using the substrate having a minute uneven structure as the wafer 201 has been described, but the present invention is not limited thereto. For example, the present invention may be applied to a process of forming an interlayer insulating film of the wafer 201 or a process of sealing the semiconductor device.

In addition, in the above-described embodiments, a case of applying the present invention to the substrate processing apparatus for processing the wafer 200 has been described, but the present invention is not limited thereto. That is, the present invention may be applied to a sealing process of a substrate including a liquid crystal in a manufacturing process of a liquid crystal device or a waterproof coating process on a glass substrate or a ceramic substrate used in various devices. In addition, the present invention may be applied to a waterproof coating treatment on a mirror.

### EXAMPLES

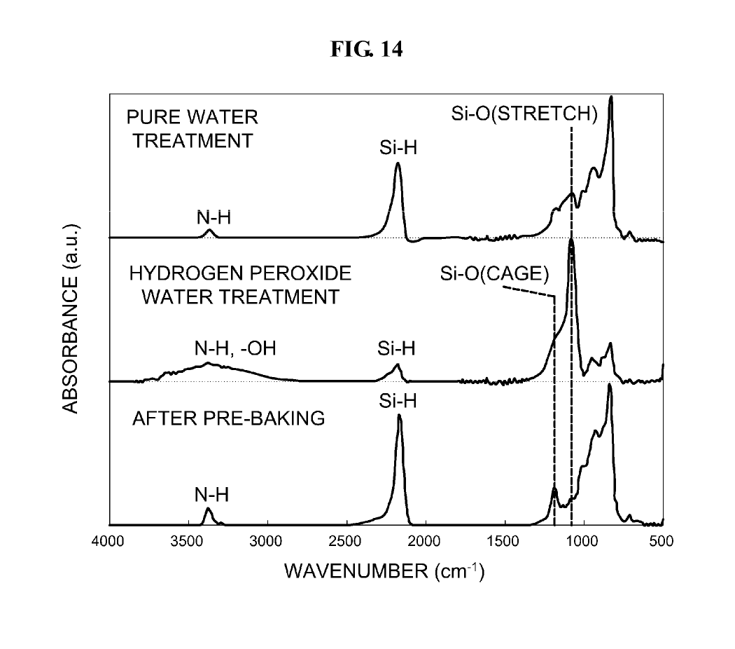

Next, Examples of the present invention will be described with reference to FIGS. 14 to 16.

In the present example, the wafer 201 including a silicon-containing film containing polysilazane was used. A film thickness of the silicon-containing film was 600 nm. First, a hardening process (pre-baking process) was performed on the wafer 201 including the silicon-containing film (Example 1).

In addition, an oxidation process (hydrogen peroxide water treatment and atmospheric pressure hydrogen peroxide water treatment) was performed on the wafer 201 (wafer 201 in Example 1) including the silicon-containing film on which the hardening process was performed in the process chamber 108 in an atmospheric pressure state at a temperature of 50° C. (Example 2). In addition, the oxidation process was performed for 30 minutes using hydrogen peroxide water having a concentration of hydrogen peroxide of 30 wt % as an oxidation solution.

In addition, pure water treatment was performed on the wafer 201 (wafer 201 of Example 1) including the silicon-containing film on which the hardening process was performed, by supplying pure water into the process chamber 108 in the atmospheric pressure state at the temperature of 50° C. (Example 3).

In addition, the oxidation process (pressurized hydrogen peroxide water treatment) was performed on the wafer 201 (wafer 201 of Example 1) including the silicon-containing film on which the hardening process was performed, in the process chamber 108 under the pressure (0.3 MPa) higher than atmospheric pressure at the temperature of 50° C. (Example 4). In addition, the oxidation process was performed for 30 minutes using the hydrogen peroxide water having a concentration of hydrogen peroxide of 30 wt % as the oxidation solution.

In addition, after performing the hardening process, a heat treatment process was performed on the wafer 201 (wafer of Example 2) on which the oxidation process was performed, in the process chamber 108 in the atmospheric pressure state at the temperature of 50° C. (Example 5). That is, a steam oxidation treatment was performed after the oxidation process (hydrogen peroxide water treatment). In addition, the heat treatment process was performed as below. First, the wafer 201 was heated to a predetermined temperature (for example, 250° C.). When the temperature of the wafer 201 reached the predetermined temperature, the wafer 201 was further heated to a predetermined temperature (400° C.) while starting supply of nitrogen gas containing water into the process chamber. When the temperature of the wafer 201 reached the predetermined temperature (400° C.), supply of water into the process chamber was stopped, and the wafer 201 was further heated to a predetermined temperature (450° C.), thereby performing the heating process for a predetermined time.

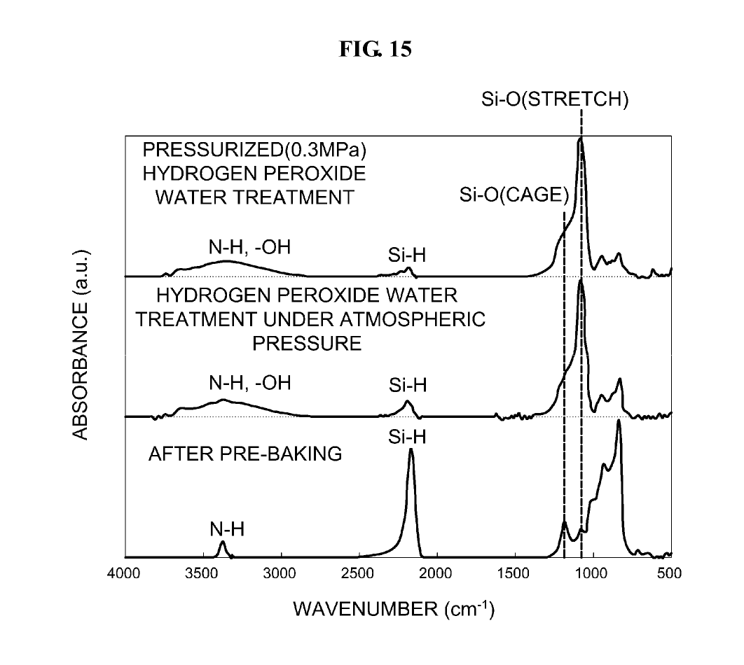

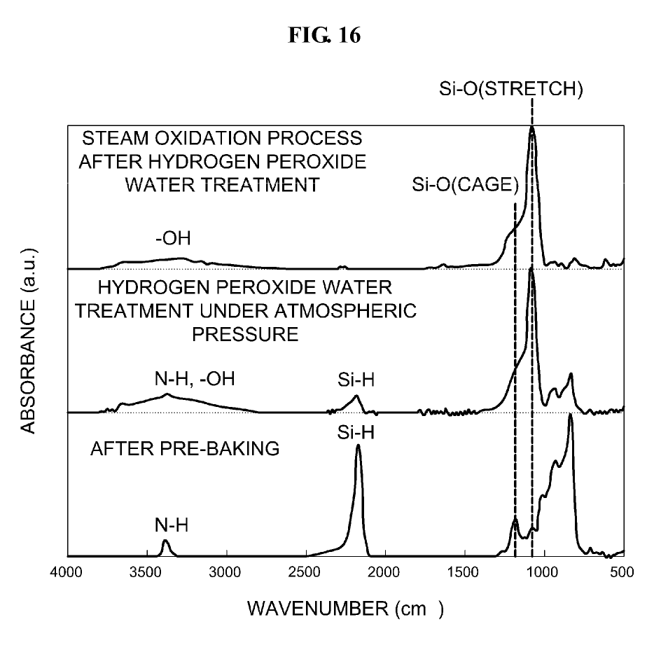

In Examples 1 to 5 described above, composition analysis of the silicon-containing film (silicon oxide film) included in the wafer 201 was performed by a Fourier transform infrared spectrometer (FT-IR). The results of the analysis are shown in FIGS. 14 to 16. That is, FIG. 14 is a graph of FT-IR spectral data of a silicon-containing film (silicon oxide film) included in a wafer 201 according to Examples 1 to 3 of the present invention. FIG. 15 is a graph of FT-IR spectral data of a silicon-containing film (silicon oxide film) included in a wafer 201 according to Examples 1, 2, and 4 of the present invention. FIG. 16 is a graph of FT-IR spectral data of a silicon-containing film (silicon oxide film) included in a wafer 201 according to Examples 1, 2, and 5 of the present invention. In addition, in FIGS. 14 to 16, the horizontal axis indicates the wave number (cm⁻¹) of infrared rays radiated onto the wafer 201, and the vertical axis indicates absorbance of infrared rays absorbed by the wafer 201.

From FIG. 14, in Example 2 in which the oxidation process was performed using the hydrogen peroxide water, it can be confirmed that clear bond vibration of a stretching motion of Si—O around the wave number of 1,090 cm⁻¹ and an asymmetric stretching motion (cage structure of Si—O) [Si—O (cage)] around the wave number of 1,240 cm⁻¹ is shown compared to Example 1. In addition, based on the comparison results of Examples 1 and 3, it can be confirmed that there is little difference in the amount of Si—H bonds of the silicon-containing film included in the wafer 201. That is, after performing the pre-baking process, it can be confirmed that hydrogen (H) that is an impurity cannot be significantly removed from the silicon-containing film even when pure water treatment is performed.

From FIG. 15, in Example 4 in which the oxidation process was performed in the process chamber under the pressure higher than atmospheric pressure, it can be confirmed that an amount of Si—H bonds around the wave number of 2,200 cm⁻¹ is reduced more and more impurities are removed than in Example 2 in which the oxidation process was performed in the process chamber in the atmospheric pressure state. In addition, it can be confirmed that the asymmetric stretching motion [Si—O(cage)] around the wave number of 1,240 cm⁻¹ and oxidation of the silicon-containing film are more clearly shown, that is, performing SiO₂ is promoted more.

From FIG. 16, in Example 5 in which the heat treatment process was performed after the oxidation process, it can be confirmed that the asymmetric stretching motion [Si—O (cage)] around the wave number of 1,240 cm⁻¹ is more clearly shown and oxidation of the silicon-containing film is further performed compared to Example 4.

That is, from Examples described above, it can be confirmed that the wafer 201 even having a minute structure can form the silicon-containing film and reform the silicon-containing film into the silicon oxide film. In addition, it can be confirmed that the wafer even having the minute structure can form a high-quality dense film without performing the process at a high temperature at which performance of a circuit itself can be degraded. In addition, the temperature at which performance of the circuit itself cannot be degraded refers to a temperature at which excessive diffusion of impurities such as boron, arsenic, and phosphorus implanted in the same operation of the transistor, condensation of electrode metal silicide, performance variation of a gate work function, degradation of a read or writing repetition life time of a memory element, or the like cannot occur.

According to the one or more embodiments of the invention set forth herein, a method of manufacturing a semiconductor device, an apparatus for manufacturing the semiconductor device, and a non-transitory computer-readable recording medium can improve the film quality of an oxide film formed on a substrate.

### Preferred Embodiment of the Present Invention

The following supplementary notes are added herein as preferred embodiments of the present invention.

[Supplementary Note 1]

According to one aspect of the present invention, there is provided a method of manufacturing a semiconductor device including: (a) loading a substrate having a silicon-containing film formed thereon into a process chamber; and (b) oxidizing the silicon-containing film by supplying a process liquid from a process liquid supply unit into the process chamber under a pressure equal to or greater than atmospheric pressure.

[Supplementary Note 2]

In the method described in supplementary note 1, the process liquid preferably includes hydrogen peroxide.

[Supplementary Note 3]

In the method described in supplementary note 1 or 2, the silicon-containing film preferably includes a silazane bond.

[Supplementary Note 4]

In the method described in any one of supplementary notes 1 to 3, the silicon-containing film preferably includes polysilazane.

[Supplementary Note 5]

Preferably, the method described in any one of supplementary notes 1 to 4 further includes (c) drying the substrate after the oxidizing.

[Supplementary Note 6]

Preferably, the method described in any one of supplementary notes 1 to 5 further includes (d) heating the substrate after the oxidizing.

[Supplementary Note 7]

In the method described in supplementary note 6, the silicon-containing film included in the substrate being heated in the step (d) includes —OH.

[Supplementary Note 8]

In the method described in supplementary note 6 or 7, the step (d) includes: supplying moisture into the process chamber; heating the substrate in the process chamber by a heating unit; and removing the moisture from the process chamber after a temperature of the substrate reaches a predetermined temperature.

[Supplementary Note 9]

Preferably, the method described in any one of supplementary notes 1 to 8 further includes (e) forming the silicon-containing film by coating a silicon-containing material on the substrate.

[Supplementary Note 10]

Preferably, the method described in supplementary note 9 further includes (f) heating the substrate after performing the step (e) to harden the silicon-containing film.

[Supplementary Note 11]

In the method described in any one of supplementary notes 1 to 10, at least the steps (b), (c) and (e) are preferably performed in the same process chamber.

[Supplementary Note 12]

In the method described in any one of supplementary notes 1 to 11, the steps (b), (c), (e) and (f) are preferably performed in the same process chamber.

[Supplementary Note 13]

In the method described in supplementary note 10, the steps (b), (e) and (f) are preferably performed in different process chambers, and the steps (b) and (c) are preferably performed in the same process chamber.

[Supplementary Note 14]

In the method described in any one of supplementary notes 1 to 13, the steps (c) and (d) are preferably performed in different process chambers.

[Supplementary Note 15]

In the method described in any one of supplementary notes 1 to 14, the step (b) is preferably performed by accommodating the substrate including a plurality of silicon-containing silicon films in the process chamber.

[Supplementary Note 16]

In the method described in any one of supplementary notes 5 to 15, the step (c) is preferably performed by accommodating the substrate including the plurality of silicon-containing films in the process chamber.

[Supplementary Note 17]

In the method described in any one of supplementary notes 6 to 16, the step (d) is preferably performed by accommodating a plurality of substrates into the process chamber after performing the step (b).

[Supplementary Note 18]

According to another aspect of the present invention, there is provided a program executable by a computer, the program includes: (a) loading a substrate having a silicon-containing film formed thereon into a process chamber; and (b) oxidizing the silicon-containing film by supplying a process liquid from a process liquid supply unit into the process chamber under a pressure equal to or greater than atmospheric pressure.

[Supplementary Note 19]

According to still another aspect of the present invention, there is provided a non-transitory computer-readable recording medium storing a program executable by a computer, the program including: (a) loading a substrate having a silicon-containing film formed thereon into a process chamber; and (b) oxidizing the silicon-containing film by supplying a process liquid from a process liquid supply unit into the process chamber under a pressure equal to or greater than atmospheric pressure.

[Supplementary Note 20]

In the recording medium described in supplementary note 19, the program preferably further includes (c) heating the substrate in the process chamber by a heating unit after performing the step (b).

[Supplementary Note 21]

In the recording medium described in supplementary note 19 or 20, the program preferably further includes (d) forming the silicon-containing film by coating a silicon-containing material on the substrate.

[Supplementary Note 22]

In the recording medium described in supplementary note 21, the program preferably further includes (e) heating the substrate to harden the silicon-containing film after performing the step (d).

[Supplementary Note 23]

According to yet another aspect of the present invention, there is provided an apparatus for manufacturing a semiconductor device including: a process chamber configured to accommodate a substrate having a silicon-containing film formed thereon; a process liquid supply unit configured to supply a process liquid into the process chamber under a pressure equal to or greater than atmospheric pressure; and a control unit configured to control at least the process liquid supply unit.

[Supplementary Note 24]

In the apparatus described in supplementary note 23, the process liquid preferably includes hydrogen peroxide.

[Supplementary Note 25]

In the apparatus described in supplementary note 23 or 24, the silicon-containing film preferably includes a silazane bond.

[Supplementary Note 26]

In the apparatus described in any one of supplementary notes 23 to 25, the silicon-containing film preferably includes polysilazane.

[Supplementary Note 27]

According to further aspect of the present invention, there is provided an apparatus for manufacturing a semiconductor device includes a plurality of process chambers configured to process a substrate; a process liquid supply unit configured to supply a process liquid into at least one of the process chamber under a pressure equal to or greater than atmospheric pressure; and a control unit configured to control at least the process liquid supply unit.

[Supplementary Note 28]

Preferably, the apparatus described in supplementary note 27 further includes a first process chamber configured to form the silicon-containing film by coating a silicon-containing material on the substrate; a second process chamber configured to supply the process liquid from the process liquid supply unit to the substrate having the silicon-containing film formed thereon; and a third process chamber configured to dry the substrate after the process liquid is supplied to the substrate.

[Supplementary Note 29]

According to further aspect of the present invention, there is provided a substrate processing apparatus including: a process chamber configured to accommodate a substrate including a silicon-containing film; a process liquid supply unit configured to supply a process liquid into the process chamber under a pressure equal to or greater than atmospheric pressure; and a control unit configured to control at least the liquid process liquid supply unit.

[Supplementary Note 30]

According to further aspect of the present invention, there is provided a substrate processing method including: (a) loading a substrate including a silicon-containing film is formed into a process chamber; and (b) oxidizing the silicon-containing film by supplying a process liquid from a process liquid supply unit into the process chamber under a pressure equal to or greater than atmospheric pressure.

[Supplementary Note 31]

According to further aspect of the present invention, there is provided a manufacturing system of a semiconductor device including a first process chamber configured to form a silicon-containing film by coating a silicon-containing material on a substrate; a second process chamber configured to supply a process liquid from a process liquid supply unit to the substrate having the silicon-containing film formed thereon; and a third process chamber configured to dry the substrate after the process liquid is supplied to the substrate.

[Supplementary Note 32]

According to further aspect of the present invention, there is provided a method of manufacturing a semiconductor device, including: (a) loading a substrate having a silicon-containing film formed thereon into a process chamber; (b) supplying a gas into the process chamber from a gas supply unit until an inner pressure of the process chamber is equal to or greater than atmospheric pressure; and (c) supplying a process liquid from a process liquid supply unit to the substrate to oxidize the silicon-containing film.

[Supplementary Note 33]

According to further aspect of the present invention, there is provided an apparatus for manufacturing a semiconductor device, including: a process chamber configured to accommodate a substrate having a silicon-containing film formed thereon; a gas supply unit configured to supply a gas into the process chamber; a process liquid supply unit configured to supply a process liquid to the substrate; and a control unit configured to control the gas supply unit and the process liquid supply unit to supply the gas into the process chamber until an inner pressure of the process chamber is equal to or greater than atmospheric pressure while simultaneously supplying the process liquid to the substrate.

[Supplementary Note 34]

According to further aspect of the present invention, there is provided a non-transitory computer-readable recording medium storing a program executable by a computer, the program including: (a) supplying a gas into a process chamber from a gas supply unit until an inner pressure of the process chamber is equal to or greater than atmospheric pressure; and (b) supplying a process liquid from a process liquid supply unit to a substrate accommodated in the process chamber and having a silicon-containing film formed thereon.

What is claimed is:

1. A method of manufacturing a semiconductor device, comprising:
(a) loading a substrate having a silicon-containing film formed thereon into a process chamber;
(b) supplying a gas into the process chamber from a gas supply unit until an inner pressure of the process chamber is equal to or greater than atmospheric pressure; and
(c) supplying a process liquid from a process liquid supply unit to the substrate to oxidize the silicon-containing film.

2. The method of claim 1, wherein the process liquid comprises hydrogen peroxide.

3. The method of claim 1, wherein the silicon-containing film comprises a silazane bond.

4. The method of claim 1, wherein the silicon-containing film comprises polysilazane.

5. The method of claim 1, further comprising (d) heating the substrate after performing the step (c).

6. The method of claim 5, wherein the silicon-containing film included in the substrate being heated in the step (d) after performing the step (c) comprises —OH.

7. The method of claim 5, wherein the step (d) comprises:
supplying moisture into the process chamber;
heating the substrate in the process chamber by a heating unit; and
removing the moisture from the process chamber after a temperature of the substrate reaches a predetermined temperature.

8. The method of claim 1, further comprising (e) forming the silicon-containing film by coating a silicon-containing material on the substrate.

9. The method of claim 8, further comprising (f) heating the substrate after performing the step (e) to harden the silicon-containing film.

10. An apparatus for manufacturing a semiconductor device, comprising:
a process chamber configured to accommodate a substrate having a silicon-containing film formed thereon;
a gas supply unit configured to supply a gas into the process chamber;
a process liquid supply unit configured to supply a process liquid to the substrate; and
a control unit configured to control the gas supply unit and the process liquid supply unit to supply the gas into the process chamber until an inner pressure of the process chamber is equal to or greater than atmospheric pressure while simultaneously supplying the process liquid to the substrate.

11. The apparatus of claim 10, wherein the process liquid comprises hydrogen peroxide.

12. The apparatus of claim 10, wherein the silicon-containing film comprises a silazane bond.

13. The apparatus of claim 10, wherein the silicon-containing film comprises polysilazane.

14. A non-transitory computer readable recording medium storing a program executable by a computer, the program comprising:
(a) supplying a gas into a process chamber from a gas supply unit until an inner pressure of the process chamber is equal to or greater than atmospheric pressure; and
(b) supplying a process liquid from a process liquid supply unit to a substrate accommodated in the process chamber and having a silicon-containing film formed thereon.

15. The non-transitory computer readable recording medium of claim 14, wherein the program further comprises (c) heating the substrate in the process chamber by a heating unit after performing the sequence (b).

16. The non-transitory computer readable recording medium of claim 14, wherein the program further comprises (d) forming the silicon-containing film by coating a silicon-containing material on the substrate.

17. The non-transitory computer readable recording medium of claim 16, wherein the program further comprises (e) heating the substrate after performing the sequence (d) to harden the silicon-containing film.
